(19) United States
(12) Patent Application Publication
(10) Pub. No.: US 2026/0333775 A1
(43) Pub. Date: Oct. 22, 2026

(54) SEMICONDUCTOR DEVICE

(71) Applicant: Samsung Electronics Co., Ltd., Suwon-si (KR)

(72) Inventors: Juho Lee, Suwon-si (KR); Seungmin Lee, Suwon-si (KR); Youngin Goh, Suwon-si (KR); Sungjin Kim, Suwon-si (KR); Mintae Ryu, Suwon-si (KR); Minhwan Lee, Suwon-si (KR); Hwayeong Lee, Suwon-si (KR)

(21) Appl. No.: 19/468,424

(22) Filed: Feb. 3, 2026

(30) Foreign Application Priority Data
Apr. 18, 2025 (KR) 10-2025-0051036

(51) Int. Cl. H10D 30/67; H10B 12/00

(52) U.S. Cl. CPC H10D 30/6757; H10B 12/482; H10B 12/488; H10D 30/6735; H10B 12/03; H10B 12/05

(57) ABSTRACT

A semiconductor device includes a substrate, channel patterns each including a first and a second side surface facing opposite directions, a bit line connected to the first side surface of each channel pattern and extending in a direction perpendicular to the upper surface of the substrate, a capacitor connected to the second side surface of each channel pattern, a word line extending across the channel patterns in a second direction intersecting the first direction, and a gate insulating layer between the channel patterns and the word line. In cross-section along the first direction and a third direction perpendicular to the substrate’s upper surface, each channel pattern includes first portions extending in the first direction and spaced apart in the third direction, and a second portion connecting the first portions, where the second portion extends in the third direction along a side surface of the capacitor in the first direction.

### CROSS-REFERENCE TO RELATED APPLICATION

This application claims priority to and the benefit of Korean Patent Application No. 10-2025-0051036 filed with the Korean Intellectual Property Office on Apr. 18, 2025, the entire contents of which are incorporated herein by reference.

### BACKGROUND

A technique for increasing the integration degree of a semiconductor device may be desired. In the case of a two-dimensional semiconductor device, the degree of integration may be determined by the area occupied by a unit memory cell, and the degree of integration in this respect may be dependent on the level of fine pattern forming technology.

### SUMMARY

In the case of fine pattern formation technology, expensive equipment may be required, so although the integration density of two-dimensional semiconductor devices may be increasing, it is still limited. Accordingly, three-dimensional semiconductor memory devices including memory cells arranged in three dimensions are being proposed.

Implementations of the present disclosure provides a semiconductor device in which gate control and carrier concentration control of the channel may be easily performed.

In some aspects, the present disclosure provides a semiconductor device including a substrate, a plurality of channel patterns spaced apart and arranged on the substrate in a direction perpendicular to an upper surface of the substrate, each of the plurality of channel patterns including a first side surface and a second side surface facing opposite directions along a first direction parallel to the upper surface of the substrate, a bit line connected to the first side surface of each of the plurality of channel patterns and extending in a direction perpendicular to the upper surface of the substrate, a capacitor connected to the second side surface of each of the plurality of channel patterns, a word line extending across the plurality of channel patterns in a second direction intersecting the first direction, and a gate insulating layer between the plurality of channel patterns and the word line. In a cross-section along the first direction and a third direction perpendicular to the upper surface of the substrate, each of the plurality of channel patterns includes first portions extending in the first direction and spaced apart in the third direction, and a second portion connecting the first portions, where the second portion extends in the third direction along a side surface of the capacitor in the first direction.

in some aspects, the present disclosure provides semiconductor device including a substrate, a plurality of channel patterns spaced apart and arranged on the substrate in a direction perpendicular to the upper surface of the substrate, each of the plurality of channel patterns including a first side surface and a second side surface facing opposite directions along a first direction parallel to the upper surface of the substrate, a bit line connected to the first side surface of each of the plurality of channel patterns and extending in a direction perpendicular to the upper surface of the substrate, a capacitor connected to the second side surface of each of the plurality of channel patterns, a word line extending across the plurality of channel patterns in a second direction intersecting the first direction, and a gate insulating layer between the plurality of channel patterns and the word line. Each of the plurality of channel patterns covers surfaces of the gate insulating layer facing each other in a third direction perpendicular to the upper surface of the substrate and a side surface of the capacitor in the first direction with a uniform thickness.

in some aspects, the present disclosure provides a semiconductor device including a substrate, a plurality of channel patterns spaced apart and arranged on the substrate in a direction perpendicular to an upper surface of the substrate, each of the plurality of channel patterns including a first side surface and a second side surface facing opposite directions along a first direction parallel to the upper surface of the substrate, a bit line connected to the first side surface of each of the plurality of channel patterns and extending in a direction perpendicular to the upper surface of the substrate, a capacitor connected to the second side surface of each of the plurality of channel patterns, a word line extending across the plurality of channel patterns in a second direction intersecting the first direction, a gate insulating layer between the plurality of channel patterns and the word line, and a spacer surrounded by each of the plurality of channel patterns and overlapping the word line in a third direction perpendicular to the upper surface of the substrate. Each of the plurality of channel patterns includes an oxide semiconductor material. The spacer includes an insulating material.

According to some implementations, gate control of the semiconductor device and carrier concentration control of the channel may be facilitated.

### BRIEF DESCRIPTION OF THE DRAWINGS

FIG. 1 is a cross-sectional view of an example of a semiconductor device.

FIG. 2 is a view showing an enlarged P1 region of FIG. 1.

FIG. 3 is a cross-sectional view taken along line I-I' of FIG. 1.

FIG. 4 is an enlarged view of the P2 region of FIG. 3.

FIG. 5 is a cross-sectional view of an example of a semiconductor device.

FIG. 6 is a cross-sectional view of an example of a semiconductor device.

FIG. 7 is a cross-sectional view of an example of a semiconductor device.

FIG. 8 is a cross-sectional view of an example of a semiconductor device.

FIGS. 9 - 61 are cross-sectional views illustrating an example method of manufacturing a semiconductor device.

### DETAILED DESCRIPTION

Hereinafter, various implementations of the present disclosure will be described in detail with reference to the accompanying drawings.

The size and thickness of each component shown in the drawings are illustrated arbitrarily for convenience of description, and the present invention is not necessarily limited to what is depicted. The thickness may be depicted in an enlarged manner in the drawings in order to clearly illustrate various layers and regions. And in the drawings, for convenience of explanation, the thicknesses of some layers and regions may be exaggerated.

In addition, when a portion such as a layer, layer, region, or plate is described as being "on" or "above" another portion, this includes not only cases in which it is directly on the other portion, but also cases in which another portion is present therebetween. Conversely, when any portion is described as being "directly on" another portion, it means that there is no other portion in between. In addition, describing that something is "on" or "above" a reference portion means that it is positioned above or below the reference portion, and does not necessarily mean that it is positioned "on" or "above" in the direction opposite to gravity.

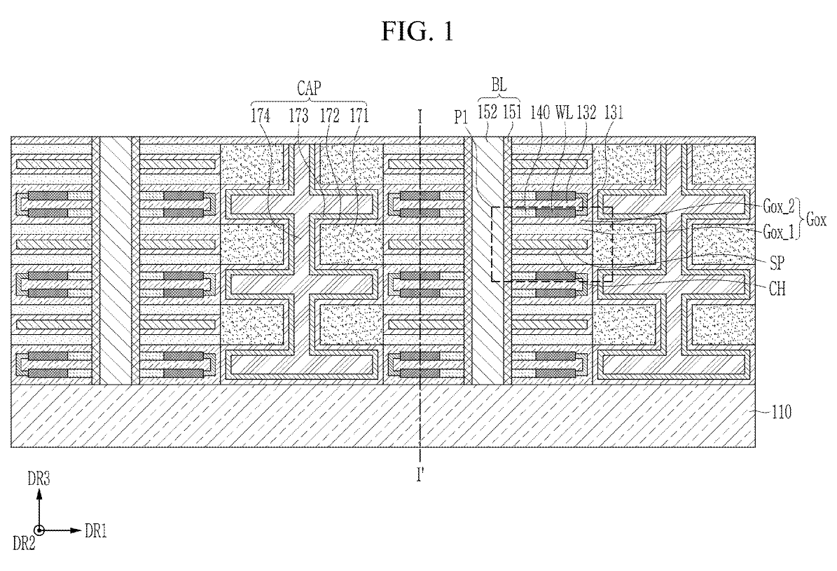

Hereinafter, a semiconductor device according to some implementations will be described with reference to FIGS. 1- 4.

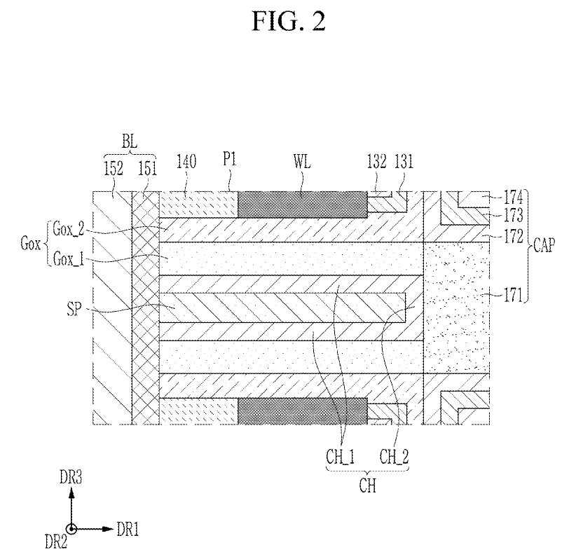

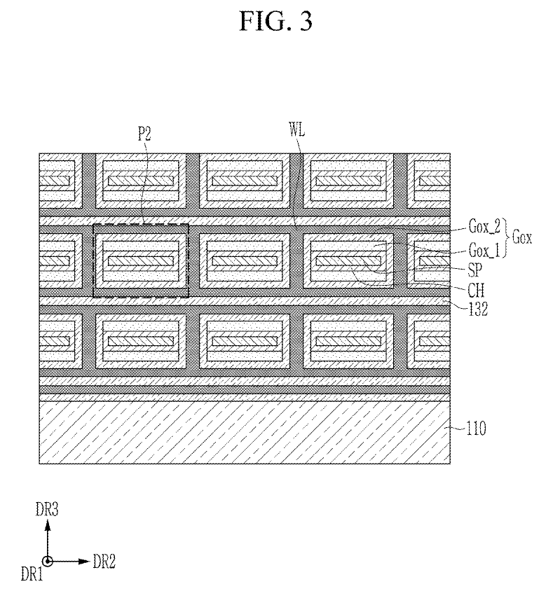

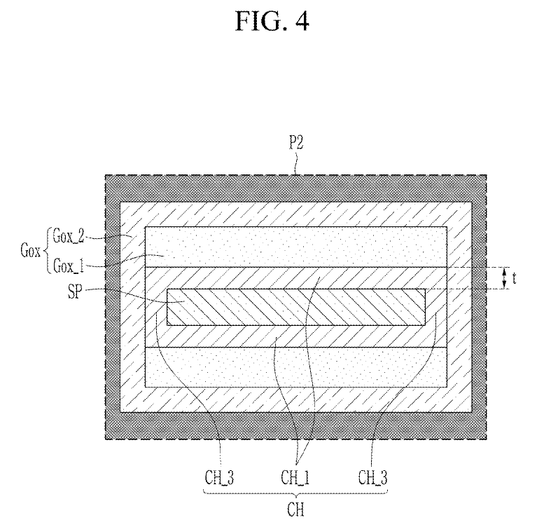

FIG. 1 is a cross-sectional view of a semiconductor device according to some implementations. FIG. 2 is an enlarged view of the P1 region of FIG. 1. FIG. 3 is a cross-sectional view taken along line I-I' of FIG. 1. FIG. 4 is an enlarged view of the P2 region of FIG. 3. FIG. 1 is a cross-sectional view taken along the first direction DR1 and the third direction DR3, and FIG. 3 is a cross-sectional view taken along the second direction DR2 and the third direction DR3.

As shown in FIGS. 1 - 4, a semiconductor device according to some implementations includes a substrate 110, and a plurality of channel patterns CH disposed on the substrate 110 and spaced apart in a third direction DR3 perpendicular to the upper surface of the substrate 110. Each of the plurality of channel patterns CH includes a first side surface and a second side surface facing opposite directions along a first direction DR1 parallel to the upper surface of the substrate 110. A semiconductor device according to some implementations includes a bit line BL connected to a first side surface of each of a plurality of channel patterns CH and extending in the third direction DR3, a capacitor CAP connected to a second side surface of each of the plurality of channel patterns CH, a word line WL extending in a second direction DR2 that intersects the first direction DR1 and crossing each of the plurality of channel patterns CH, and a gate insulating layer Gox positioned between each of the plurality of channel patterns CH and the word line WL. The second direction DR2 is parallel to the upper surface of the substrate 110 and is a direction intersecting the first direction DR1. For example, the second direction DR2 may be a direction orthogonal to the first direction DR1.

The substrate 110 may include a semiconductor material. For example, the substrate 110 may include a Group IV semiconductor, a Group III-V compound semiconductor, a Group II-VI compound semiconductor, and the like. For example, the substrate 110 may include a semiconductor such as Si or Ge, or a compound semiconductor such as SiGe, SiC, GaAs, InAs, or InP. For example, the substrate 110 may be a single crystal epitaxial layer grown on a single crystal silicon substrate. However, the material of the substrate 110 is not limited thereto and may be variously modified.

A plurality of channel patterns CH may be positioned on the substrate 110. The plurality of channel patterns CH may be arranged spaced apart in the third direction DR3. The plurality of channel patterns CH may be spaced apart and disposed in the first direction DR1. The bit line BL may be positioned between channel patterns CH adjacent in the first direction DR1. The capacitor CAP may be positioned between channel patterns CH adjacent in the first direction DR1. The bit line BL and the capacitor CAP may be alternately and repeatedly arranged along the first direction DR1. The plurality of channel patterns CH may be spaced apart and arranged in the second direction DR2.

Each of the plurality of channel patterns CH may extend in the first direction DR1, and may have a pillar shape with an empty interior. Each of the plurality of channel patterns CH may include one end portion opened along the first direction DR1 and the other end portion closed. One end portion of each channel pattern CH faces the bit line BL, and the other end portion of each channel pattern CH may face the capacitor CAP.

Each of the plurality of channel patterns CH may include the first side surface and the second side surface facing opposite directions along the first direction DR1. The first side surface of each channel pattern CH may be connected to the bit line BL. For example, the first side surface of the channel pattern CH may contact the bit line BL, but is not limited thereto. Another layer may be further positioned between the channel pattern CH and the bit line BL. The second side surface of the channel pattern CH may be connected to the capacitor CAP. For example, the second side surface of the channel pattern CH may be in contact with the capacitor CAP, but is not limited thereto. Another layer may be further positioned between the channel pattern CH and the capacitor CAP.

Each channel pattern CH of the plurality may include an oxide semiconductor material. For example, each channel pattern CH may include IGZO (Indium Gallium Zinc Oxide), but is not limited thereto.

The bit line BL may extend in the third direction DR3. The bit line BL may be connected to first side surfaces of a plurality of channel patterns CH which are spaced apart and arranged in the third direction DR3. The plurality of channel patterns CH spaced apart and arranged in the third direction DR3 may be electrically connected to one bit line BL. A semiconductor device according to some implementations may include a plurality of bit lines BL. The plurality of bit lines BL may be spaced apart and arranged in the first direction DR1. The plurality of bit lines BL spaced apart and arranged in the first direction DR1 may each be connected to the plurality of channel patterns CH spaced apart and arranged in the first direction DR1. Two channel patterns CH adjacent in the first direction DR1 may be connected to one bit line BL. The plurality of bit lines BL may be spaced apart and arranged in the second direction DR2. The plurality of bit lines BL spaced apart and arranged in the second direction DR2 may each be connected to the plurality of channel patterns CH spaced apart and arranged in the second direction DR2.

The bit line BL may include a conductive material. In some implementations, the bit line BL may include the first conductive layer 151 and the second conductive layer 152. The first conductive layer 151 may be positioned on the plurality of channel patterns CH. The second conductive layer 152 may be positioned on the first conductive layer 151. The second conductive layer 152 may have a pillar shape extending in the third direction DR3. The first conductive layer 151 may surround the outer surface of the second conductive layer 152. The first conductive layer 151 may be positioned between the second conductive layer 152 and the plurality of channel patterns CH. For example, the first conductive layer 151 may be in contact with the plurality of channel patterns CH.

The first conductive layer 151 may include an oxide semiconductor material. For example, the first conductive layer 151 may include the same oxide semiconductor material as the channel pattern CH, but is not limited thereto. The first conductive layer 151 may include an oxide semiconductor material different from the channel pattern CH. As the first conductive layer 151 includes a material identical or similar to the channel pattern CH, the contact resistance between the bit line BL and the channel pattern CH may be reduced.

The second conductive layer 152 may include a doped semiconductor material such as doped silicon or doped germanium, a conductive metal nitride such as titanium nitride or tantalum nitride, a metal such as tungsten, titanium, or tantalum, a metal-semiconductor compound such as tungsten silicide, cobalt silicide, or titanium silicide, or a combination thereof.

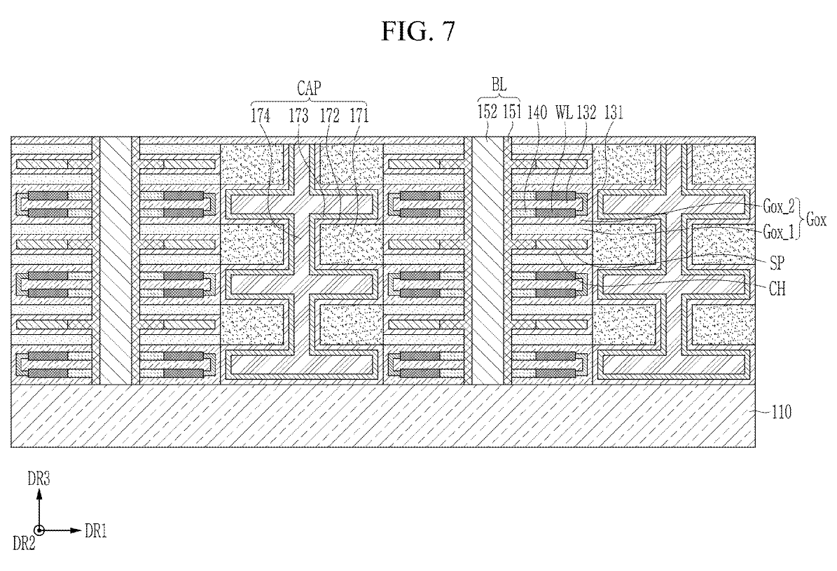

However, it is not limited to the above-described implementation. For example, the bit line BL may be formed as a single layer. This implementation will be described below with reference to FIG. 7.

In FIG. 1, the bit line BL is shown as being connected to the substrate 110, but the bit line BL and the substrate 110 may be electrically insulated. Although not shown, an insulating layer may be positioned between the substrate 110 and the bit line BL.

The capacitor CAP may include a first capacitor electrode 171, a second capacitor electrode 173, a dielectric layer 172 positioned between the first capacitor electrode 171 and the second capacitor electrode 173, and a plate electrode 174 positioned on the second capacitor electrode 173. The first capacitor electrode 171 may be connected to the second side surface of the channel pattern CH.

A semiconductor device according to some implementations may include a plurality of capacitors CAP. Each of the plurality of capacitors CAP may include the first capacitor electrode 171. A semiconductor device according to some implementations may include a plurality of first capacitor electrodes 171. The plurality of first capacitor electrodes 171 may be spaced apart and arranged in the third direction DR3. The plurality of first capacitor electrodes 171 spaced apart and arranged in the third direction DR3 may each be connected to the plurality of channel patterns CH spaced apart and arranged in the third direction DR3. The plurality of first capacitor electrodes 171 may be spaced apart and arranged in the first direction DR1. The plurality of first capacitor electrodes 171 spaced apart and arranged in the first direction DR1 may each be connected to the plurality of channel patterns CH spaced apart and arranged in the first direction DR1. The plurality of first capacitor electrodes 171 may be spaced apart and arranged in the second direction DR2. The plurality of first capacitor electrodes 171 spaced apart and arranged in the second direction DR2 may each be connected to the plurality of channel patterns CH spaced apart and arranged in the second direction DR2.

The dielectric layer 172 may cover the surface of the first capacitor electrode 171. The dielectric layer 172 may cover surfaces of the first capacitor electrode 171 except for the surface connected to the channel pattern CH. The dielectric layer 172 may cover the plurality of first capacitor electrodes 171 that are spaced apart and arranged in the third direction DR3 and the second direction DR2. The dielectric layer 172 may cover two first capacitor electrodes 171 adjacent to each other in the first direction DR1. The dielectric layer 172 may cover two first capacitor electrodes 171 positioned to face each other in the first direction DR1 between two bit lines BL adjacent in the first direction DR1.

The second capacitor electrode 173 may cover the surface of the dielectric layer 172. The second capacitor electrode 173 may be spaced apart from the first capacitor electrode 171 by the dielectric layer 172. The plate electrode 174 may cover the surface of the second capacitor electrode 173. The plate electrode 174 may be connected to the second capacitor electrode 173. Between two bit lines BL adjacent in the first direction DR1, the dielectric layer 172, the second capacitor electrode 173, and the plate electrode 174 of the plurality of capacitors CAP facing each other in the first direction DR1 and spaced apart in the third direction DR3 and the second direction DR2 may each be integrally formed.

The first capacitor electrode 171, the second capacitor electrode 173, and the plate electrode 174 may each include a conductive material. The first capacitor electrode 171, the second capacitor electrode 173, and the plate electrode 174 each may include at least one of a metal material such as titanium, tantalum, tungsten, copper, or aluminum, a conductive metal nitride such as titanium nitride or tantalum nitride, or a doped semiconductor material such as doped silicon or doped germanium. The first capacitor electrode 171 and the second capacitor electrode 173 may include the same material. The plate electrode 174 may include a different material from the first capacitor electrode 171 and the second capacitor electrode 173. For example, the first capacitor electrode 171 and the second capacitor electrode 173 may include titanium nitride, and the plate electrode 174 may include doped silicon germanium.

Meanwhile, the plate electrode 174 may form an upper electrode of the capacitor CAP together with the second capacitor electrode 173, but the present disclosure is not limited thereto. For example, in some implementations, the plate electrode 174 may be made of a dielectric material instead of a conductive material. In this case, the plate electrode 174 does not operate as the upper electrode of the capacitor CAP, and may serve as an insulating layer or a protective layer that covers the second capacitor electrode 173.

The dielectric layer 172 may include at least one of a dielectric, a ferromagnetic material, or an antiferromagnetic material. The dielectric may include a high dielectric constant material. For example, the dielectric may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof.

The word line WL may extend in the second direction DR2. The word line WL may cross each of the plurality of channel patterns CH. The word line WL may cross the plurality of channel patterns CH that are spaced apart and arranged in the second direction DR2. The plurality of channel patterns CH spaced apart and arranged in the second direction DR2 may be electrically connected to one word line WL.

In some implementations, the word line WL may overlap the channel pattern CH in the third direction DR3 and the second direction DR2. The word line WL may surround a portion of the surface of the channel pattern CH. The word line WL may surround a portion of the outer peripheral surface of the channel pattern CH with the first direction DR1 as a central axis. The word line WL may surround the portion between both end portions of the channel pattern CH along the first direction DR1. A channel may be formed along the surface of the channel pattern CH surrounded by the word line WL.

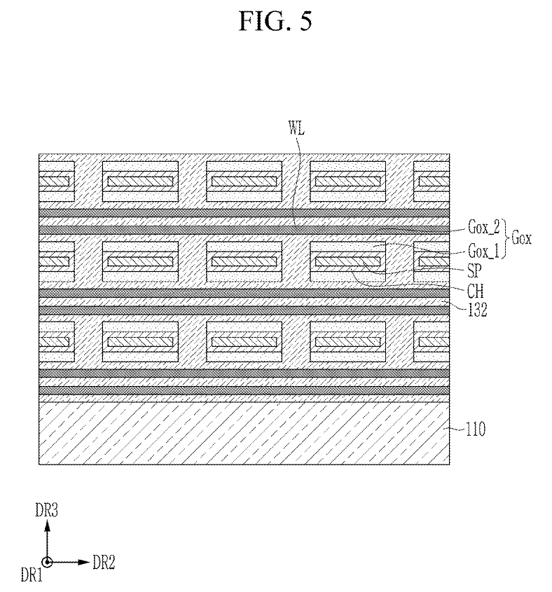

However, it is not limited to the above-described implementations. For example, the word line WL may overlap the channel pattern CH only in the third direction DR3, and may not overlap in the second direction DR2. This implementation will be described below with reference to FIG. 5.

A semiconductor device according to some implementations may include a plurality of word lines WL. The plurality of word lines WL may be arranged spaced apart in the third direction DR3. The plurality of word lines WL spaced apart and arranged in the third direction DR3 may cross each of a plurality of channel patterns CH spaced apart and arranged in the third direction DR3. The plurality of word lines WL spaced apart and arranged in the third direction DR3 may each be electrically connected to the plurality of channel patterns CH spaced apart and arranged in the third direction DR3.

The plurality of word lines WL may be spaced apart and arranged in the first direction DR1. The plurality of word lines WL spaced apart and arranged in the first direction DR1 may cross the plurality of channel patterns CH spaced apart and arranged in the first direction, respectively. The plurality of word lines WL spaced apart and arranged in the first direction DR1 may each be electrically connected to the plurality of channel patterns CH spaced apart and arranged in the first direction DR1.

The gate insulating layer Gox may be positioned between the word line WL and the channel pattern CH. The word line WL may be spaced apart from the surface of the channel pattern CH by the gate insulating layer Gox.

In some implementations, the gate insulating layer Gox may include a first gate insulating layer Gox_1 and a second gate insulating layer Gox_2. The first gate insulating layer Gox_1 may be positioned between the channel pattern CH and the second gate insulating layer Gox_2. The second gate insulating layer Gox_2 may be positioned between the word line WL and the first gate insulating layer Gox_1, and between the word line WL and the channel pattern CH. The first gate insulating layer Gox_1 may cover the side surface in the third direction DR3 among the outer surfaces of the channel pattern CH. The second gate insulating layer Gox_2 may cover both side surfaces in the third direction DR3 and both side surfaces in the second direction DR2 among the outer surfaces of the channel pattern CH.

However, it is not limited to the above-described implementation. For example, among the first gate insulating layer Gox_1 and the second gate insulating layer Gox_2, the first gate insulating layer Gox_1 may be omitted.

The word line WL may include a conductive material. For example, the word line WL may include a doped semiconductor material such as doped silicon or doped germanium; a conductive metal nitride such as titanium nitride or tantalum nitride; a metal such as tungsten, titanium, or tantalum; a metal-semiconductor compound such as tungsten silicide, cobalt silicide, or titanium silicide; or a combination thereof.

The first gate insulating layer Gox_1 and the second gate insulating layer Gox_2 may each include at least one of a high dielectric constant material, silicon oxide, silicon nitride, or silicon oxynitride. A high dielectric constant material may include at least one selected from the group consisting of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

A semiconductor device according to some implementations may include a first insulating pattern 131, a second insulating pattern 132, and a third insulating pattern 140. The first insulating pattern 131, the second insulating pattern 132, and the third insulating pattern 140 may be positioned between the plurality of channel patterns CH spaced apart and arranged in the third direction DR3. The first insulating pattern 131 may be positioned between the word line WL and the capacitor CAP in the first direction DR1. The first insulating pattern 131 may be positioned between the second insulating pattern 132 and the capacitor CAP in the first direction DR1. The second gate insulating layer Gox_2 may be positioned between the first insulating pattern 131 and the capacitor CAP in the first direction DR1. The first insulating pattern 131 may be positioned between the second gate insulating layer Gox_2 and the second insulating pattern 132 in the third direction DR3. The second insulating pattern 132 may be positioned between a plurality of word lines WL spaced apart and arranged in the third direction DR3. The second insulating pattern 132 may be positioned between the first insulating pattern 131 and the bit line BL in the first direction DR1. The third insulating pattern 140 may be positioned between the word line WL and the bit line BL in the first direction DR1. The word line WL may be spaced apart from the bit line BL by the third insulating pattern 140. The third insulating pattern 140 may be positioned between the second gate insulating layer Gox_2 and the second insulating pattern 132 in the third direction DR3.

Hereinafter, the shape of the channel pattern CH and the spacer SP will be described in detail with reference to FIG. 2 and FIG. 4.

In a cross-section along the first direction DR1 and the third direction DR3, the channel pattern CH may include first portions CH_1 extending in the first direction DR1 and a second portion CH_2 connecting the first portions CH_1. On the cross-section along the first direction DR1 and the third direction DR3, the first portions CH_1 of the channel pattern CH may be spaced apart in the third direction DR3. The second portion CH_2 of the channel pattern CH may connect the first portions CH_1 of the channel pattern CH spaced apart in the third direction DR3 in the third direction DR3. The second portion CH_2 may extend in the third direction DR3 along the side surface of the first capacitor electrode 171 in the first direction DR1.

In a cross-section along the first direction DR1 and the third direction DR3, the channel pattern CH may cover, with a uniform thickness, the surfaces of the first gate insulating layer Gox_1 facing each other in the third direction DR3 and the side surface of the first capacitor electrode 171 in the first direction DR1. The first portions CH_1 of the channel pattern CH may cover surfaces of the first gate insulating layer Gox_1 facing each other in the third direction DR3. The second portion CH_2 of the channel pattern CH may cover a side surface of the first capacitor electrode 171 in the first direction DR1. The thickness of the first portions CH_1 in the third direction DR3 may be identical to the thickness of the second portion CH_2 in the first direction DR1.

The second portion CH_2 of the channel pattern CH may be connected to the first capacitor electrode 171. For example, the second portion CH_2 of the channel pattern CH may contact a side surface of the first capacitor electrode 171 in the first direction DR1, but is not limited thereto. Another layer may be further positioned between the second portion CH_2 of the channel pattern CH and the side surface of the first capacitor electrode 171 in the first direction DR1.

The first portions CH_1 of the channel pattern CH may be connected to the bit line BL. For example, the first portions CH_1 of the channel pattern CH may contact a side surface of the bit line BL in the first direction DR1, but are not limited thereto. Another layer may be further positioned between the first portions CH_1 of the channel pattern CH and the side surface of the bit line BL in the first direction DR1.

The channel pattern CH may overlap the word line WL in the third direction DR3. The first portions CH_1 of the channel pattern CH may overlap the word line WL in the third direction DR3. The channel pattern CH may overlap the word line WL in the second direction DR2. In a cross-section along the second direction DR2 and the third direction DR3, the channel pattern CH may be surrounded by the word line WL. In a cross-section along the second direction DR2 and the third direction DR3, the channel pattern CH may have a ring shape. For example, the channel pattern CH may include the first portions CH_1 spaced apart in the third direction DR3 in the word line WL, and third portions CH_3 spaced apart in the second direction DR2. Both end portions of a first portion CH_1 in the second direction DR2 may be connected respectively to both end portions of another first portion CH_1 in the second direction DR2 by the third portion CH_3. Both end portions of the third portion CH_3 in the third direction DR3 may be connected, by the first portion CH_1, to both end portions of another third portion CH_3 in the third direction DR3, respectively.

In cross-sections along the second direction DR2 and the third direction DR3, the channel pattern CH may cover, with a uniform thickness, the surfaces of the first gate insulating layer Gox_1 that face each other in the third direction DR3 and the surfaces of the second gate insulating layer Gox_2 that face each other in the second direction DR2. The first portions CH_1 of the channel pattern CH may cover surfaces of the first gate insulating layer Gox_1 facing each other in the third direction DR3. The third portions CH_3 of the channel pattern CH may cover surfaces of the second gate insulating layer Gox_2 facing each other in the second direction DR2. The thickness of the first portions CH_1 in the third direction DR3 may be identical to the thickness of the third portions CH_3 in the second direction DR2.

In some implementations, the thickness t of the channel pattern CH may be about 2 nm to about 4 nm. The thickness of the channel pattern CH may be the thickness t of each of the first portions CH_1 in the third direction DR3. The thickness of the channel pattern CH may be a thickness of each third portion CH_3 in the second direction DR2.

A semiconductor device according to some implementations may include a spacer SP positioned between first portions CH_1 of the channel pattern CH, and between the second portion CH_2 of the channel pattern CH and the bit line BL. The spacer SP may be surrounded by the channel pattern CH. In a cross-section along the first direction DR1 and the third direction DR3, the spacer SP may be positioned inside a space surrounded by the first portions CH_1 and the second portion CH_2 of the channel pattern CH. In cross-sections along the second direction DR2 and the third direction DR3, the spacer SP may be positioned inside a space surrounded by the first portions CH_1 and the third portions CH_3 of the channel pattern CH. The spacer SP may be positioned between the first portions CH_1 of the channel pattern CH, and between the third portions CH_3 of the channel pattern CH.

The second portion CH_2 may be positioned between the spacer SP and the first capacitor electrode 171. The spacer SP may be spaced apart from the first capacitor electrode 171 by the channel pattern CH. The spacer SP may extend in the first direction DR1 from the inner side of the second portion CH_2 of the channel pattern CH toward the bit line BL. For example, the spacer SP may contact the bit line BL. However, the implementation is not limited thereto. For example, the spacer SP may be spaced apart from the bit line BL in a first direction DR1, and an air gap may be positioned between the spacer SP and the bit line BL.

The spacer SP may overlap with the word line WL and the third direction DR3. A width of the spacer SP in the first direction DR1, in a region overlapping the word line WL in the third direction DR3, may be the same as a width of the word line WL in the first direction DR1.

The distance between the spacer SP and the bit line BL in the first direction DR1 may be equal to or shorter than the distance between the word line WL and the bit line BL in the first direction DR1. For example, as shown in FIG. 2, the word line WL may be spaced apart from the bit line BL by the third insulating pattern 140, and the spacer SP may be in contact with the bit line BL. In this case, a distance between the spacer SP and the bit line BL in the first direction DR1 may be shorter than a distance between the word line WL and the bit line BL in the first direction DR1. In another example, an air gap may be positioned between the spacer SP and the bit line BL, and a width of the air gap in the first direction DR1 may be the same as or less than a width of the third insulating pattern 140 in the first direction DR1. In this case, the distance between the spacer SP and the bit line BL in the first direction DR1 may be equal to or shorter than the distance between the word line WL and the bit line BL in the first direction DR1.

The spacer SP may include an insulating material. For example, the insulating material may include oxides such as SiOx, Al₂O₃, HfO₂, or GaOx, and nitrides such as SiN. However, the insulating material is not limited thereto, and may include other different dielectric materials.

In some implementations, the channel pattern CH covers the inner surface of the space surrounded by the word line WL and the gate insulating layer Gox with a uniform thickness, and may include an empty space therein. The channel pattern CH may surround an internal empty space with an axis extending along the first direction DR1 as a central axis. For example, the channel pattern CH may include, in a cross-section along the first direction DR1 and the third direction DR3, the first portions CH_1 spaced apart in the third direction DR3 and the second portion CH_2 connecting the first portions CH_1. In the comparative example, the channel pattern CH completely fills the space surrounded by the word line WL and the gate insulating layer Gox, and may not include an empty space therein. For example, the channel pattern CH may have a rod shape extending in the first direction DR1 and, in a cross-section along the first direction DR1 and the third direction DR3, may be in contact with surfaces of the gate insulating layer Gox facing each other in the third direction DR3. In some implementations, the thickness of the channel pattern CH may be about 2 nm to about 4 nm, which may be thinner than the thickness of the channel pattern CH in the comparative example. As the thickness of the channel pattern CH is about 2 nm to about 4 nm, the threshold voltage (Vth) and subthreshold swing characteristics of the gate corresponding to the word line WL may be improved, thereby facilitating gate control.

In some implementations, the channel pattern CH may include an oxide semiconductor material. When the channel pattern CH includes an oxide semiconductor material, an annealing process may be performed under an O2 or air atmosphere in order to control the carrier concentration of the channel pattern CH. During the annealing process, O may diffuse into the channel pattern CH, but the diffusion rate of O in the oxide semiconductor material may be very slow. Accordingly, it may be difficult to adjust the carrier concentration of the channel pattern CH to a desired concentration.

For example, the annealing process may be performed after forming the channel pattern CH and before forming the spacer SP. In this case, the spacer SP is not limited to oxide insulating materials, and may include various insulating materials such as nitride insulating materials. In some implementations, since the channel pattern CH includes an empty space therein, the area in which O₂ or air is in contact with the channel pattern CH during the annealing process may increase. According to the above-described comparative example, only the side surface of the channel pattern CH in the first direction DR1 may contact O₂ or air. On the other hand, according to some implementations, not only the side surface of the channel pattern CH in the first direction DR1 but also the surfaces of the channel pattern CH facing each other in the third direction DR3 surrounding an internal empty space, and the surfaces of the channel pattern CH facing each other in the second direction DR2, may be in contact with O₂ or air. Accordingly, O may be diffused throughout the channel pattern CH, so that it may be easy to adjust the carrier concentration of the channel pattern CH to a desired concentration.

As another example, the annealing process may be performed after both the channel pattern CH and the spacer SP are formed. In this case, the spacer SP may include an oxide insulating material. Since the diffusion rate of O is fast in the oxide insulating material, O may rapidly diffuse throughout the spacer SP, and O may be diffused overall into the channel pattern CH through the surfaces of the channel pattern CH facing each other in the third direction DR3 and in the second direction DR2 which are in contact with the spacer SP. Accordingly, even when an annealing process is performed with the spacer SP formed inside the channel pattern CH, the carrier concentration of the channel pattern CH may be adjusted to a desired concentration.

Hereinafter, a modified implementation of the implementation shown in FIGS. 1-4 will be described with reference to FIG. 5.

FIG. 5 is a cross-sectional view of a semiconductor device according to some implementations. FIG. 5 may be a cross-sectional view taken along line I-I' of FIG. 1. The implementation shown in FIG. 5 may have a shape and structure of the word line WL that are partially different from those of the implementations shown in FIGS. 1 - 4. In the implementation shown in FIG. 5, the same reference numerals may be referred to for components identical to those in the implementations shown in FIGS. 1 - 4. Hereinafter, differences from the implementations shown in FIGS. 1 - 4 will be mainly described.

As shown in FIG. 5, the word line WL may include a first word line WL1 and a second word line WL2. The first word line WL1 and the second word line WL2 may be positioned respectively on both sides of the channel pattern CH in the third direction DR3. The first word line WL1 may extend in the second direction DR2 in one side of the channel pattern CH in the third direction DR3. The second word line WL2 may extend in the second direction DR2 in the other side of the channel pattern CH in the third direction DR3. The first word line WL1 and the second word line WL2 may overlap the channel pattern CH and the third direction DR3, and may not overlap in the second direction DR2.

The first word line WL1 and the second word line WL2 may respectively serve as gates. The first word line WL1 and the second word line WL2 may operate as a double gate with respect to one channel pattern CH. One of the first word line WL1 and the second word line WL2 may be referred to as a front gate, and the other may be referred to as a back gate.

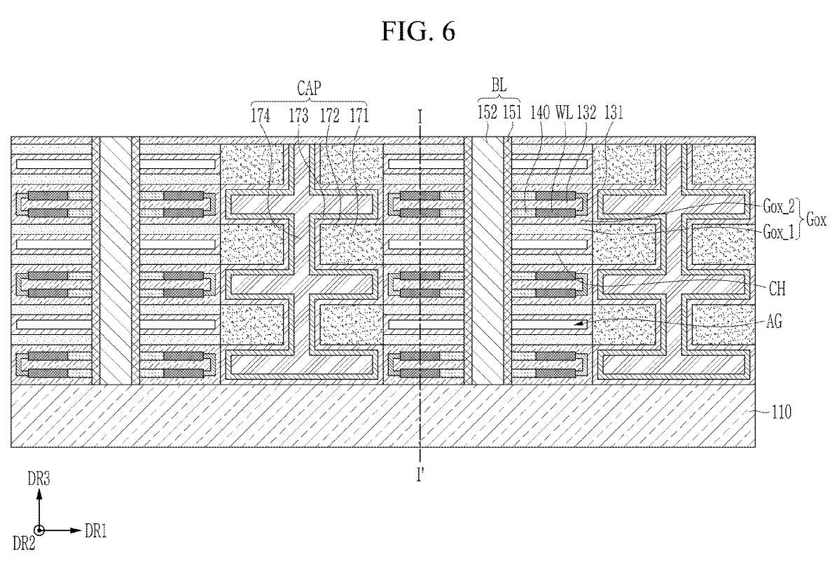

Hereinafter, with reference to FIG. 6, a modification of the implementation shown in FIGS. 1 - 4 will be described.

FIG. 6 is a cross-sectional view of a semiconductor device according to some implementations. The implementation shown in FIG. 6 may be partially different from the implementations shown in FIGS. 1 - 4 in that the spacer SP is omitted. In the implementation shown in FIG. 6, the same reference numerals may be referred to for the same components as those shown in the implementations illustrated in FIGS. 1 -4. Hereinafter, differences from the implementations shown in FIGS. 1 -4 will be mainly described.

As shown in FIG. 6, an air gap AG may be positioned in a space surrounded by the channel pattern CH. The air gap AG may be positioned between inner surfaces of channel patterns CH facing each other in the third direction DR3. The air gap AG may be positioned between the inner surface of the channel pattern CH and the outer surface of the bit line BL that face each other in the first direction DR1. The air gap AG may overlap the word line WL in the third direction DR3. The width of the region where the air gap AG and the word line WL overlap in the third direction DR3 along the first direction DR1 may be the same as the width of the word line WL along the first direction DR1.

A space surrounded by the channel pattern CH may have a diameter in a direction perpendicular to a central axis extending along the first direction DR1. The diameter may be referred to as the inner diameter of the channel pattern CH. For example, the inner diameter of the channel pattern CH may be the width in the third direction DR3 between the inner surfaces of the channel pattern CH that face each other in the third direction DR3. For example, when an inner diameter of the channel pattern CH is less than or equal to a threshold value, even if a deposition process is performed on an end portion of the channel pattern CH in the first direction DR1 that is open toward the bit line BL, the deposition material may not fill the interior of the space surrounded by the channel pattern CH. Subsequently, the bit line BL may be formed covering the open end portion of the channel pattern CH. The bit line BL is also formed on the side surface of the channel pattern CH in the first direction DR1, and may be hardly formed in the space surrounded by the channel pattern CH. Accordingly, an air gap AG may be formed naturally in the interior space surrounded by the channel pattern CH and the bit line BL.

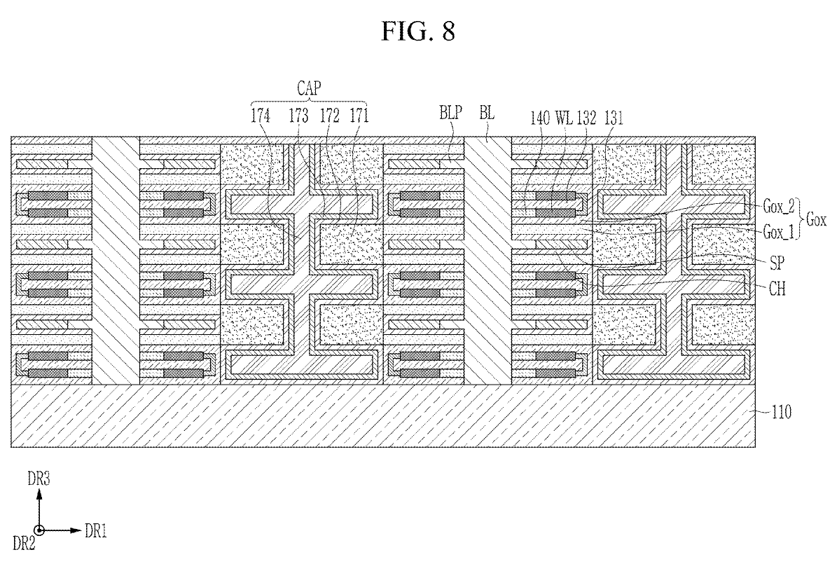

Hereinafter, with reference to FIG. 7 and FIG. 8, modifications of the implementations shown in FIGS. 1- 4 will be described.

FIG. 7 is a cross-sectional view of a semiconductor device according to some implementations. FIG. 8 is a cross-sectional view of a semiconductor device according to some implementations. FIG. 7 and FIG. 8 illustrate implementations in which the shape and structure of the bit line BL may be partially different from the implementations illustrated in FIGS. 1 -4. In the implementations shown in FIG. 7 and FIG. 8, the same reference numerals may be used for the same components as those shown in the implementations of FIGS. 1 -4. Hereinafter, differences from the implementation illustrated in FIGS. 1 -4 will be mainly described.

As shown in FIG. 7 and FIG. 8, the bit line BL may overlap the plurality of channel patterns CH in the first direction DR1 and the third direction DR3. A portion of the bit line BL extending in the third direction DR3 may overlap the plurality of channel patterns CH in the first direction DR1. The bit line BL may include a plurality of protrusion portions BLP protruding in the first direction DR1. The plurality of protrusion portions BLP may overlap the plurality of channel patterns CH in the third direction DR3. Each of the plurality of protrusion portions BLP may be surrounded by each of the plurality of channel patterns CH. Each of the plurality of protrusion portions BLP may be positioned inside a space surrounded by each of the plurality of channel patterns CH. In a cross-section along the first direction DR1 and the third direction DR3, each of the plurality of protrusion portions BLP may extend in the first direction DR1 and be positioned between first portions of each of the plurality of channel patterns CH that are spaced apart in the third direction DR3. Each of the plurality protrusion portion BLP may be positioned between inner surfaces of each of the plurality channel pattern CH facing each other in the third direction DR3.

In the implementations illustrated in FIG. 7 and FIG. 8, the plurality of protrusion portions BLP of the bit line BL may be in contact with the plurality of channel patterns CH in the third direction DR3. In the implementations shown in FIGS. 1 - 4, the bit line BL may contact the plurality of channel patterns CH only in the first direction DR1, whereas in the implementations shown in FIG. 7 and FIG. 8, the bit line BL may contact the plurality of channel patterns CH not only in the first direction DR1 but also in the third direction DR3. Accordingly, in the implementations shown in FIG. 7 and FIG. 8, the contact area between the bit line BL and the channel pattern CH may be larger than the contact area between the bit line BL and the channel pattern CH in the implementations shown in FIGS. 1 - 4.

In the implementations illustrated in FIG. 7 and FIG. 8, the length of the spacer SP in the first direction DR1 may be shorter than the length of the spacer SP in the first direction DR1 in the implementations illustrated in FIGS. 1 - 4. However, also in the implementations shown in FIG. 7 and FIG. 8, as in the implementation shown in FIGS. 1- 4, the spacer SP may overlap the word line WL in the third direction DR3, and the width, in the first direction, of a region of the spacer SP overlapping the word line WL in the third direction DR3, may be identical to the width of the word line WL in the first direction DR1. In the implementations shown in FIG. 7 and FIG. 8, a side surface of the spacer SP in the first direction DR1 facing the capacitor CAP may be adjacent to the capacitor CAP more than a side surface of the word line WL in the first direction DR1 facing the capacitor CAP. The distance by which the other side surface of the spacer SP facing the bit line BL is spaced apart from the capacitor CAP in the first direction DR1 may be the same as or greater than the distance by which the other side surface of the word line WL facing the bit line BL is spaced apart from the capacitor CAP in the first direction DR1. Each of the plurality of protrusion portions BLP may not overlap the word line WL in the third direction DR3.

The implementation shown in FIG. 7 is such that the bit line BL may include the first conductive layer 151 and the second conductive layer 152. The first conductive layer 151 is positioned on the plurality of channel patterns CH, and the second conductive layer 152 may be positioned on the first conductive layer 151. The first conductive layer 151 may be in contact with the plurality of channel patterns CH. The second conductive layer 152 may be spaced apart from the plurality of channel patterns CH by the first conductive layer 151. The second conductive layer 152 may have a pillar shape extending in the third direction DR3. The first conductive layer 151 surrounds the outer surface of the second conductive layer 152, and may extend in the third direction DR3. The first conductive layer 151 may include the plurality of protrusion portions BLP protruding in the first direction DR1.

In some implementations, since the channel pattern CH includes an oxide semiconductor material, the first conductive layer 151 may also include an oxide semiconductor material. For example, the first conductive layer 151 may include the same oxide semiconductor material as the channel pattern CH, but is not limited thereto. The first conductive layer 151 may include an oxide semiconductor material different from the channel pattern CH.

In some implementations, as the first conductive layer 151 includes an oxide semiconductor material, the plurality of protrusion portions may include an oxide semiconductor material. For example, the plurality of protrusion portions BLP may include the same oxide semiconductor material as the channel pattern CH, but is not limited thereto. The plurality of protrusion portions BLP may include an oxide semiconductor material different from the channel pattern CH.

The implementation shown in FIG. 8 may have the bit line BL formed as a single layer. The bit line BL may have a pillar shape extending in the third direction DR3. The bit line BL may include the plurality of protrusion portions BLP protruding in the first direction DR1.

As described above, the bit line BL may be in contact with the plurality of channel patterns CH. The plurality of protrusion portions BLP of the bit line BL may be in contact with the plurality of channel patterns CH in the third direction DR3. In the implementations shown in FIGS. 1- 4, the bit line BL may contact the plurality of channel patterns CH only in the first direction DR1. However, in the implementation shown in FIG. 8, the bit line BL may contact the plurality of channel patterns CH not only in the first direction DR1 but also in the third direction DR3. Accordingly, in the implementation shown in FIG. 8, the contact area between the bit line BL and the channel pattern CH may be larger than the contact area between the bit line BL and the channel pattern CH in the implementations shown in FIGS. 1 - 4.

In some implementations, the bit line BL may include a different conductive material from the channel pattern CH including an oxide semiconductor material. For example, the bit line BL may include a doped semiconductor material such as doped silicon or doped germanium, a conductive metal nitride such as titanium nitride or tantalum nitride, a metal such as tungsten, titanium, or tantalum, a metal-semiconductor compound such as tungsten silicide, cobalt silicide, or titanium silicide, or a combination thereof.

In the implementation shown in FIG. 8, as the bit line BL includes a different conductive material from the channel pattern CH including an oxide semiconductor material, the contact resistance between the bit line BL and the channel pattern CH may be greater than that of the implementations shown in FIGS. 1 - 4, where the first conductive layer 151 of the bit line BL in contact with the channel pattern CH includes an oxide semiconductor material. However, in the implementation shown in FIG. 8, since the contact area between the bit line BL and the channel pattern CH is larger than in the implementations shown in FIGS. 1 -4, the contact resistance between the bit line BL and the channel pattern CH may be reduced.

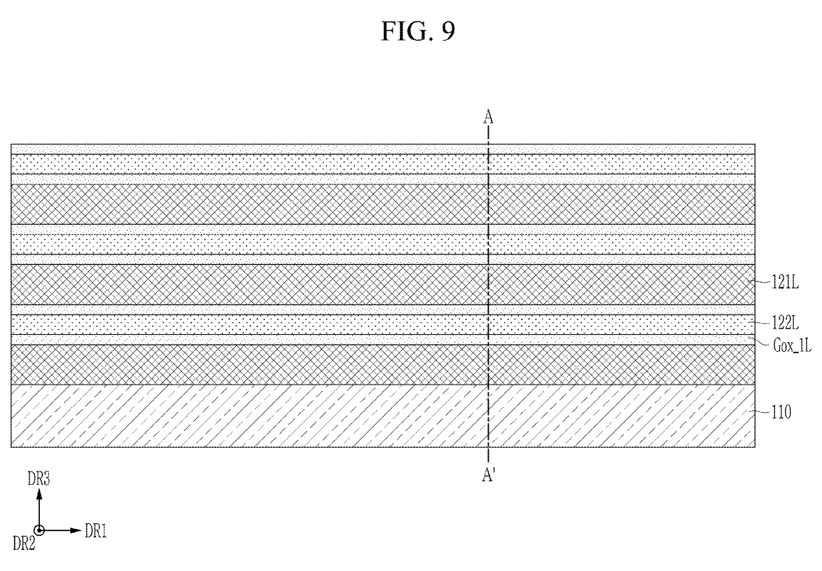

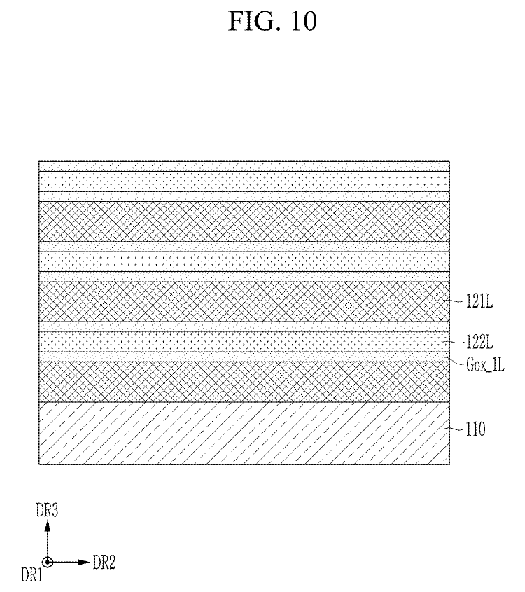

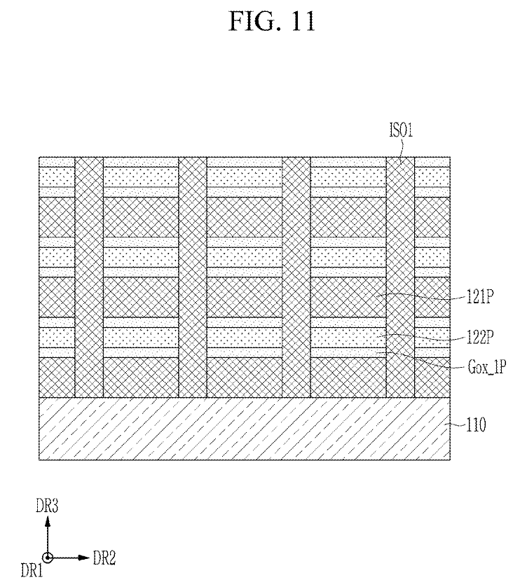

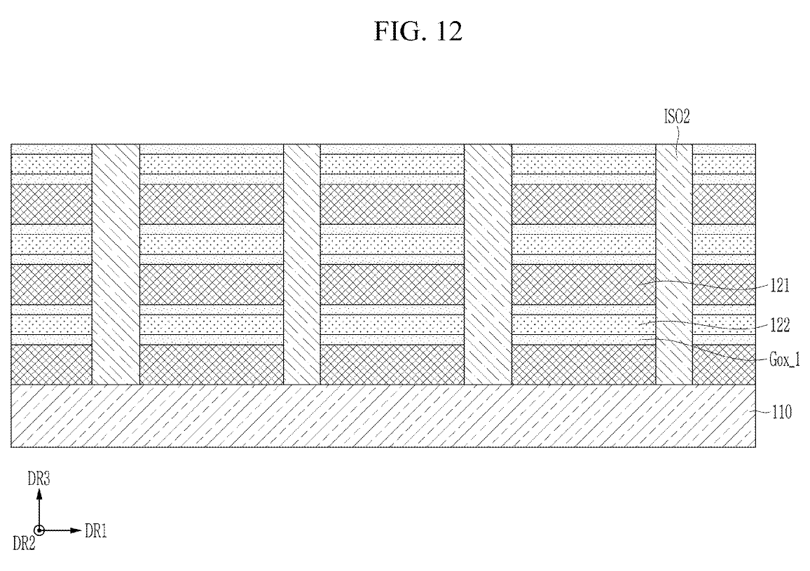

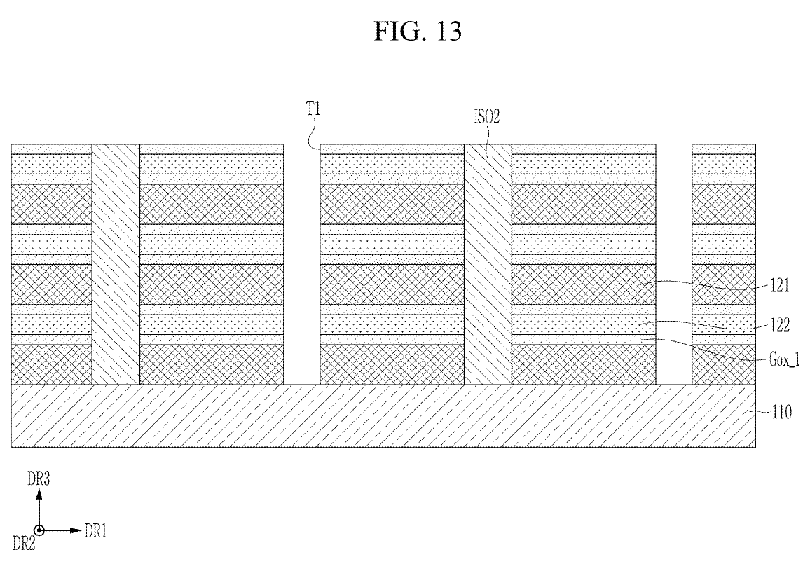

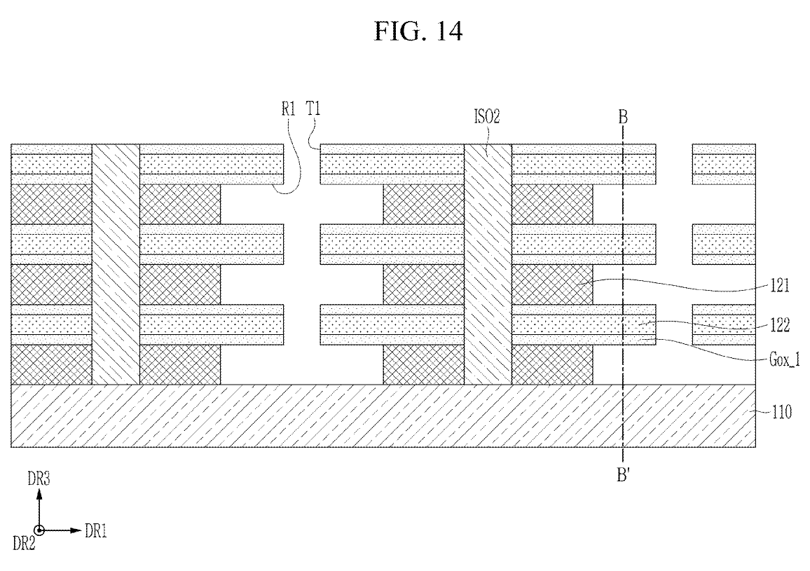

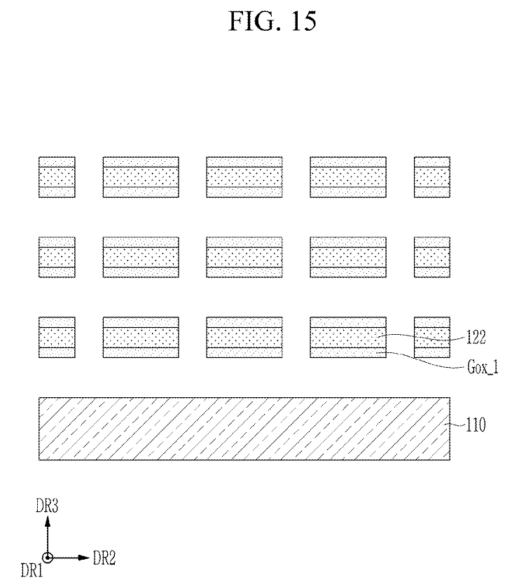

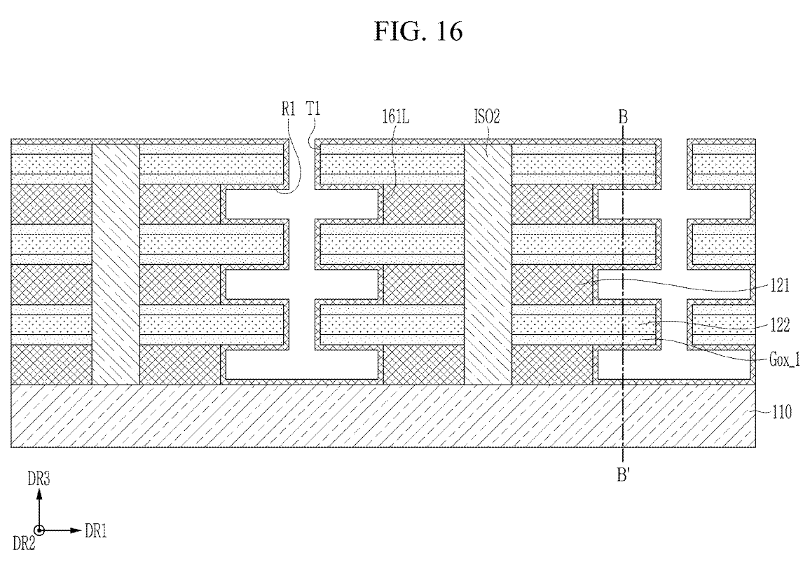

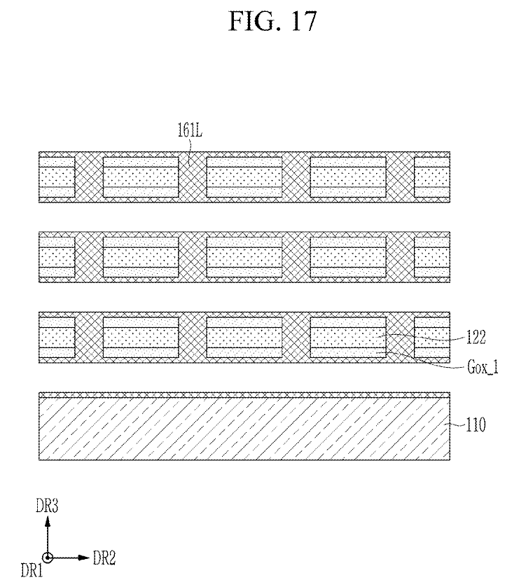

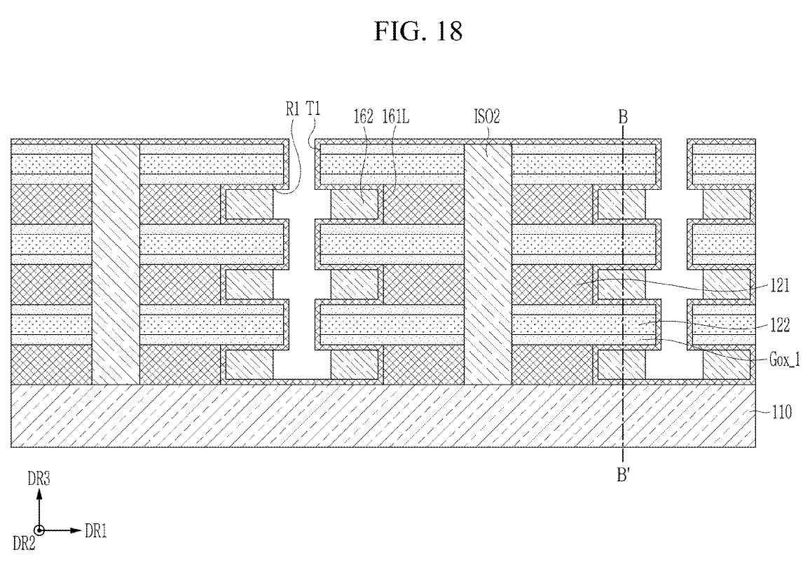

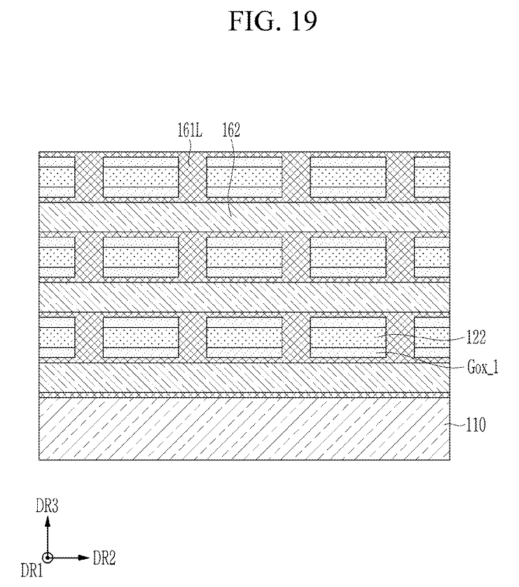

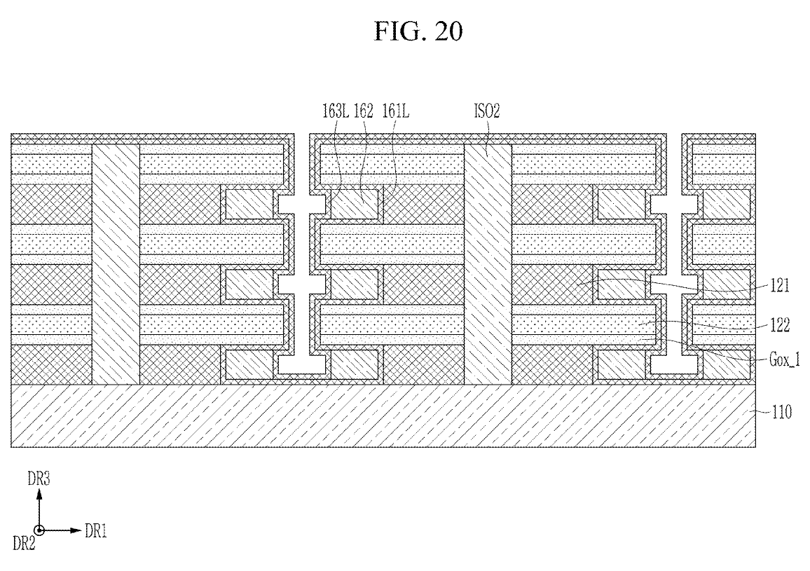

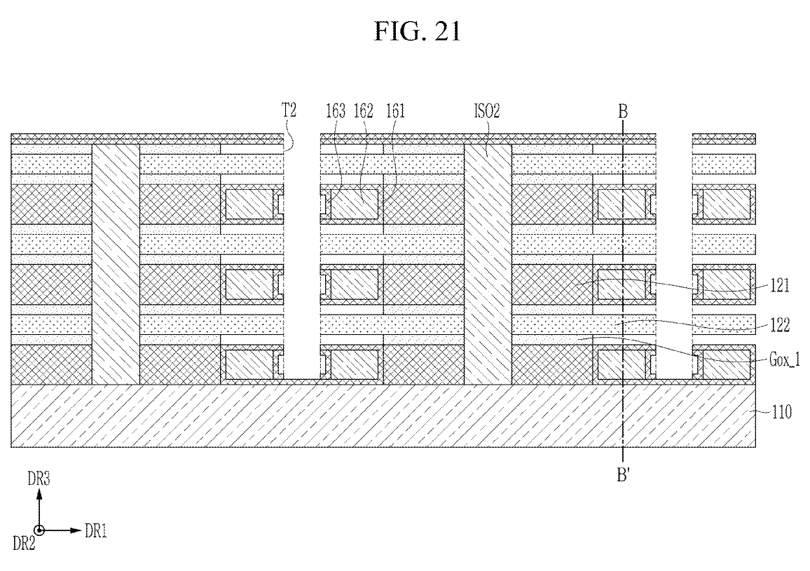

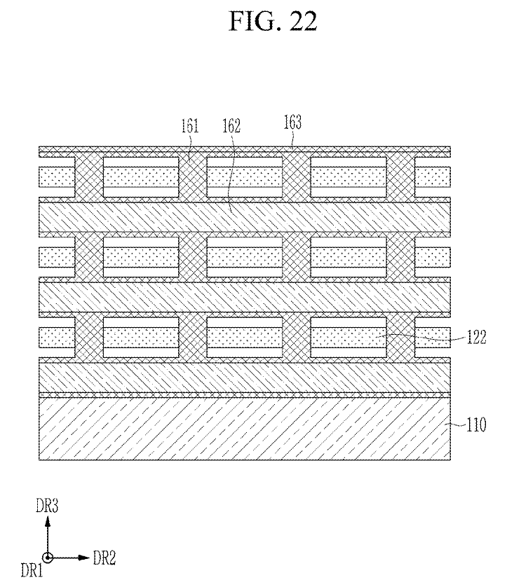

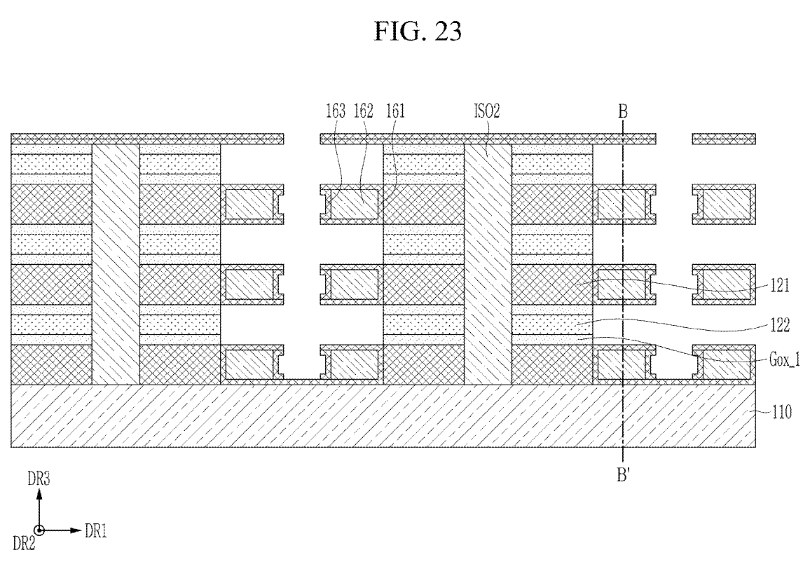

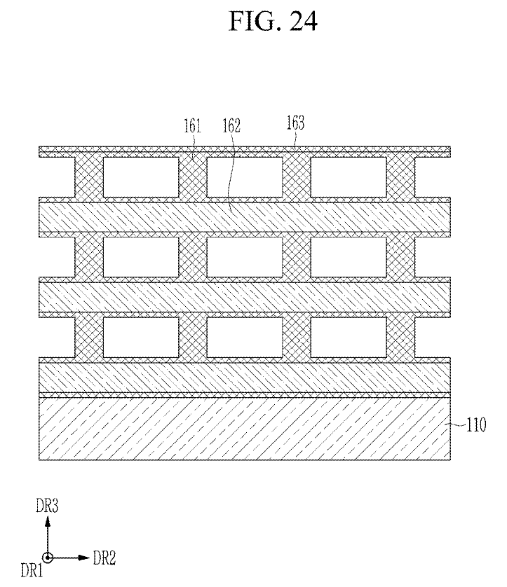

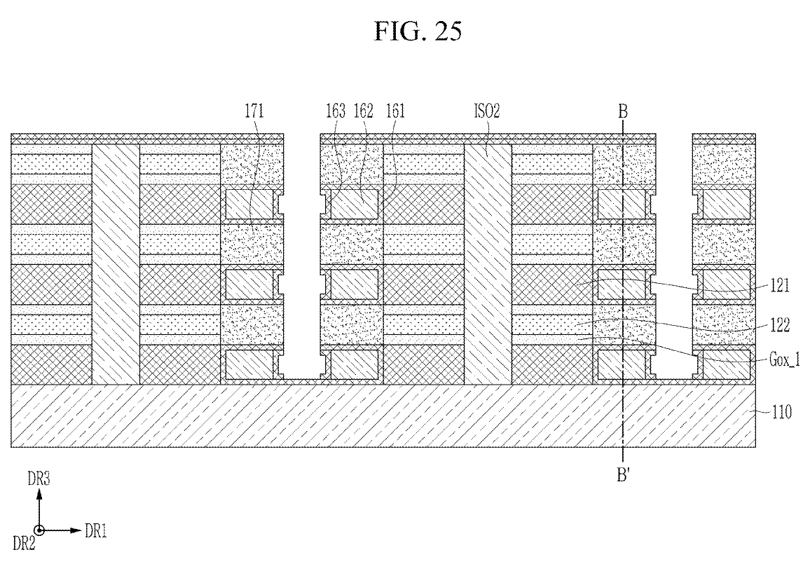

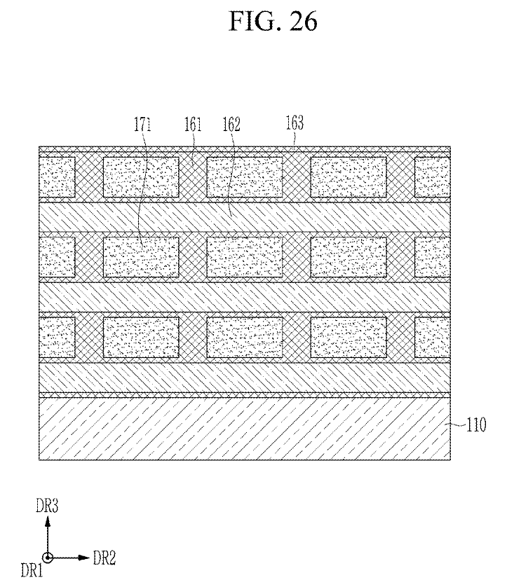

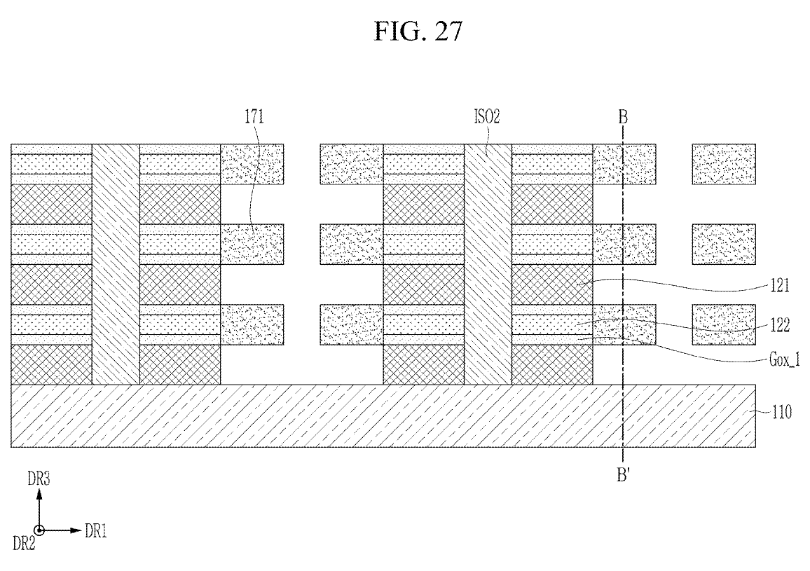

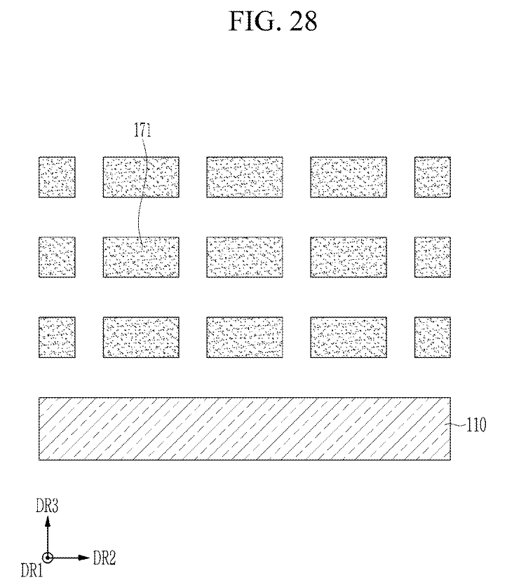

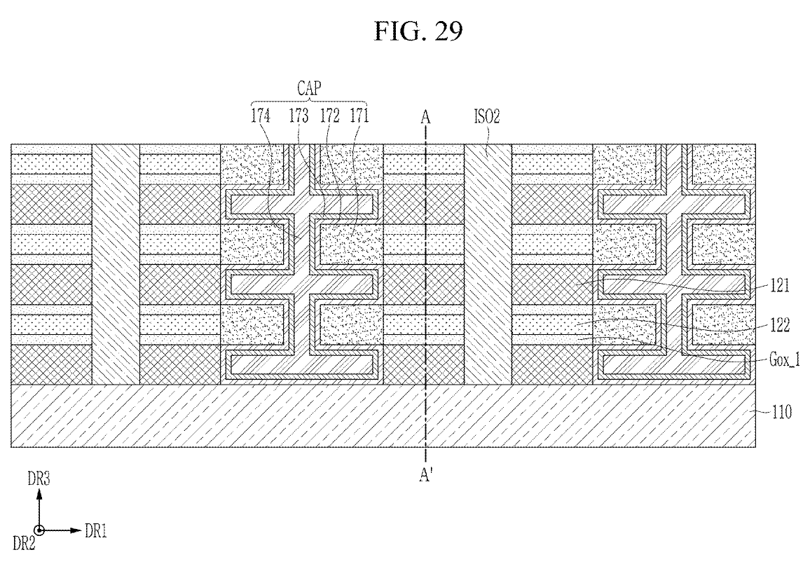

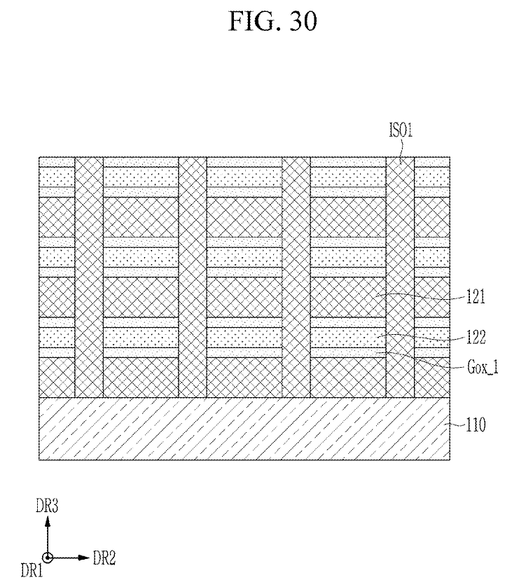

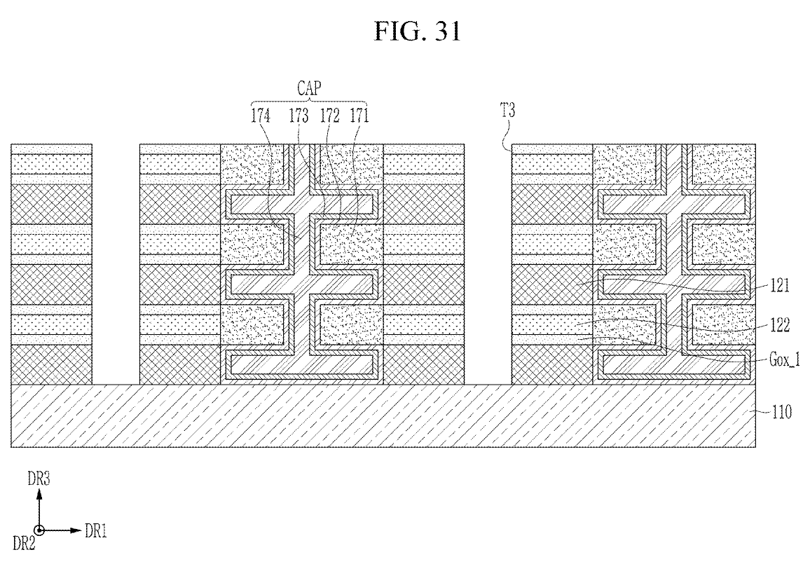

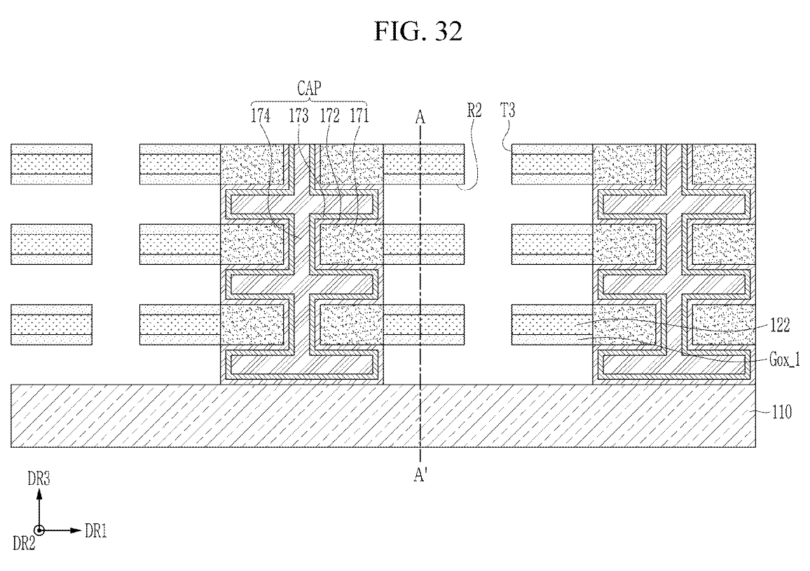

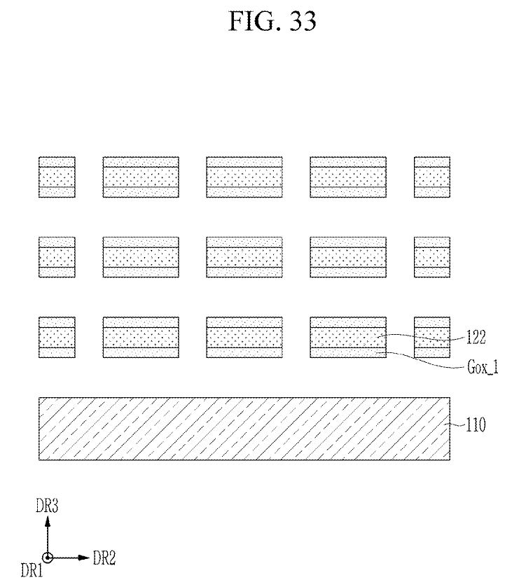

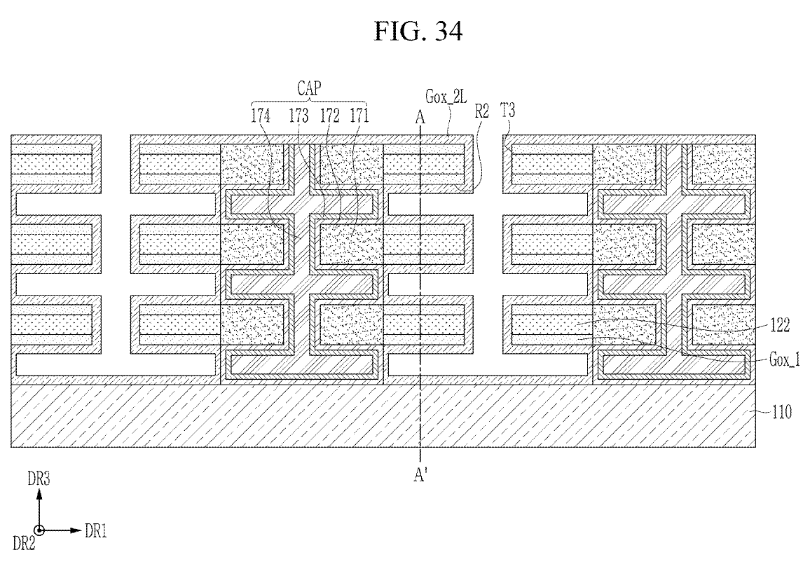

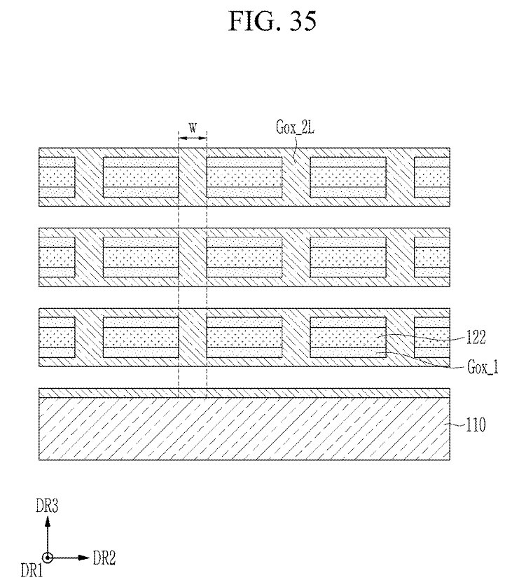

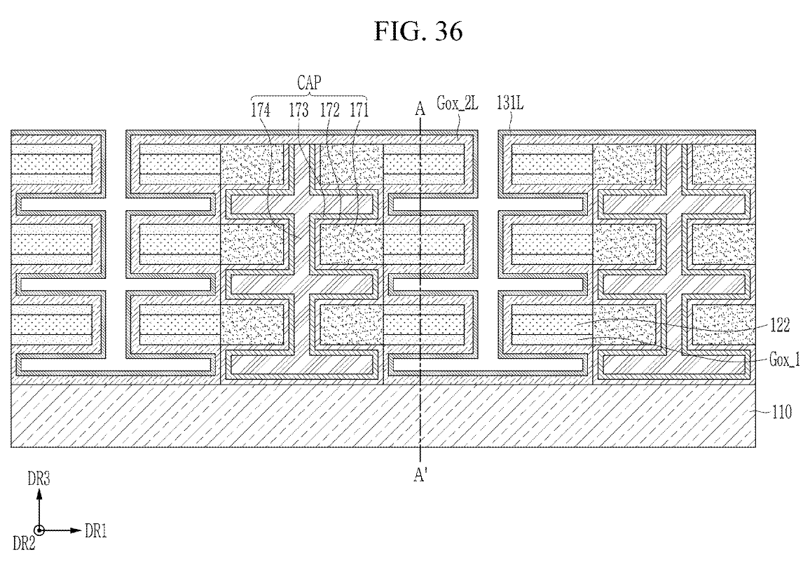

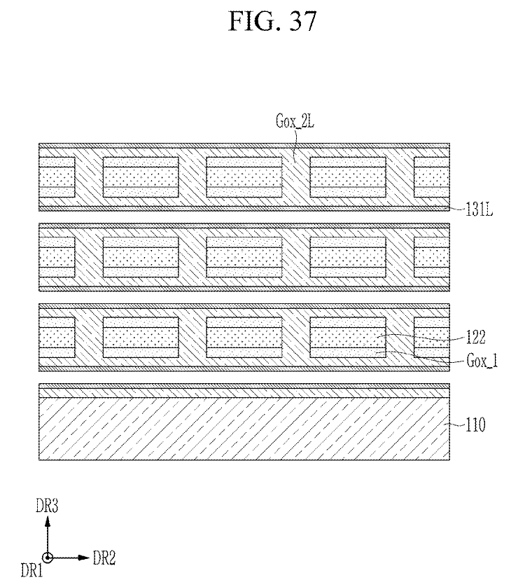

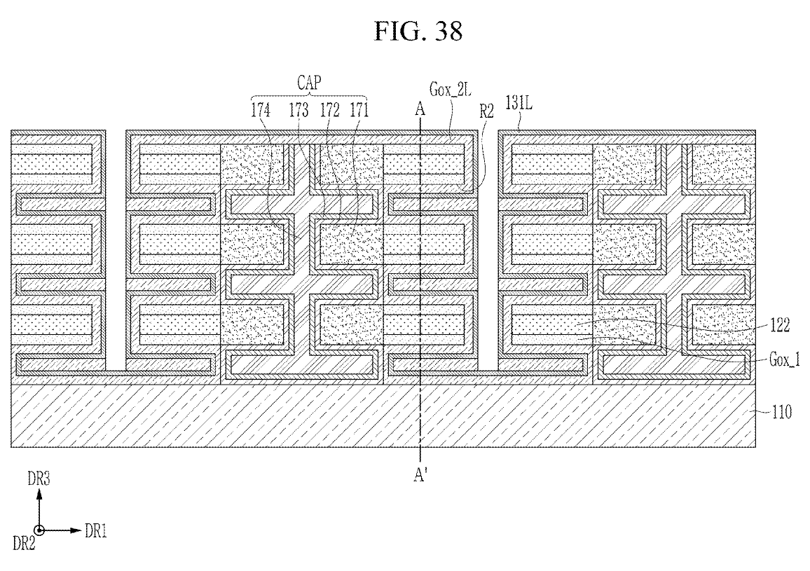

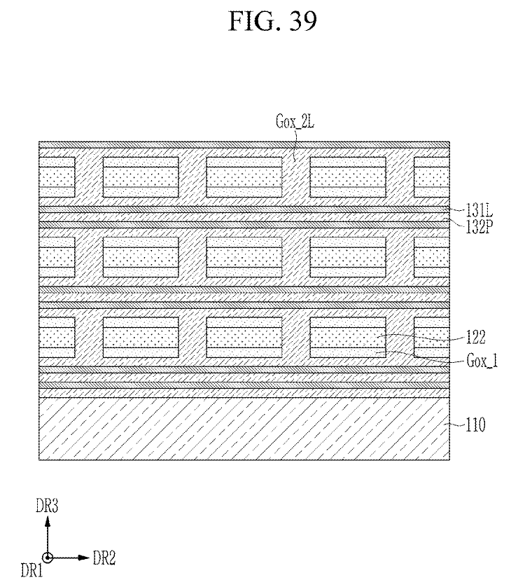

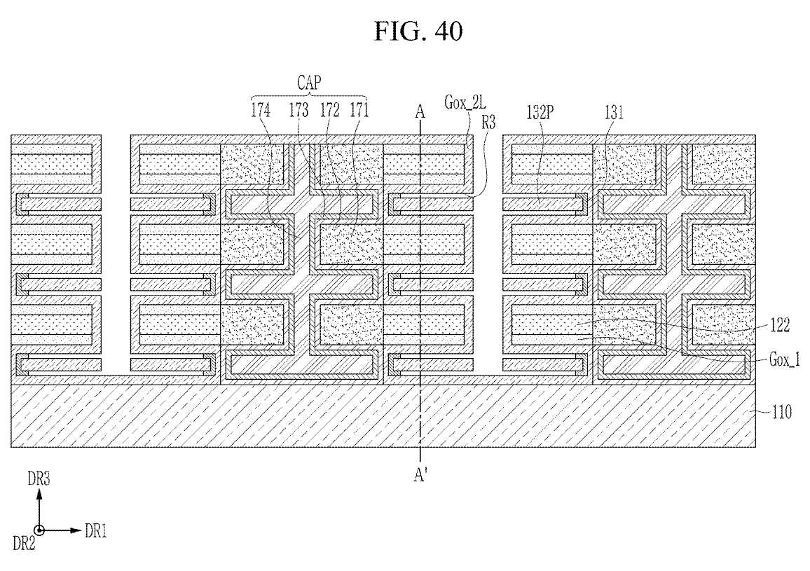

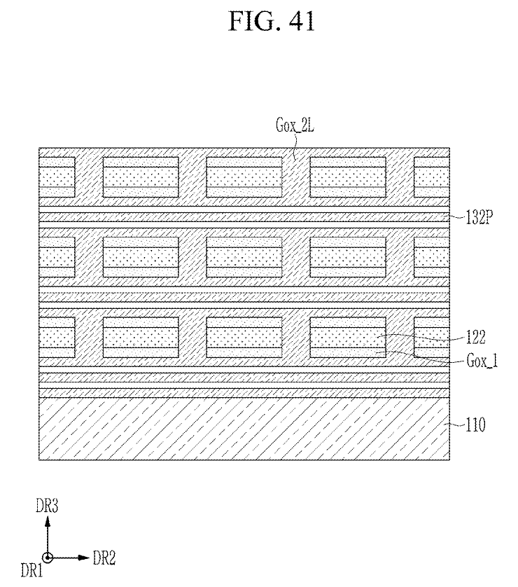

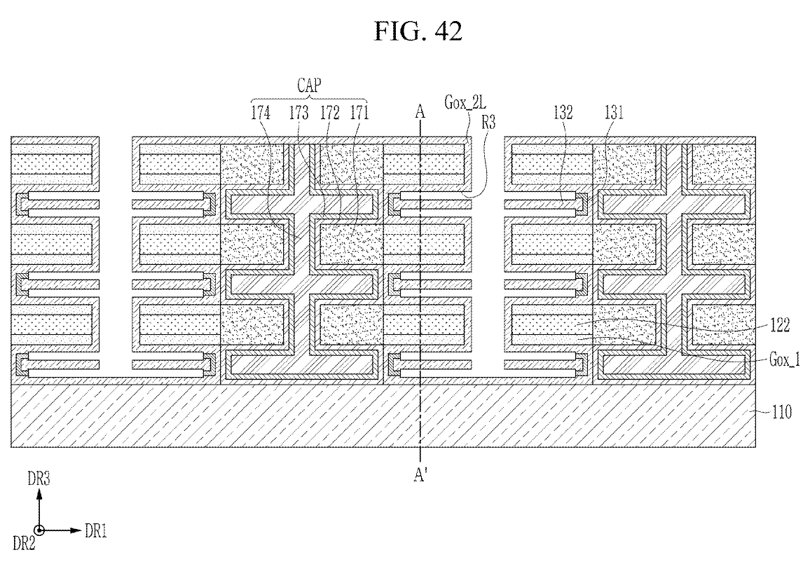

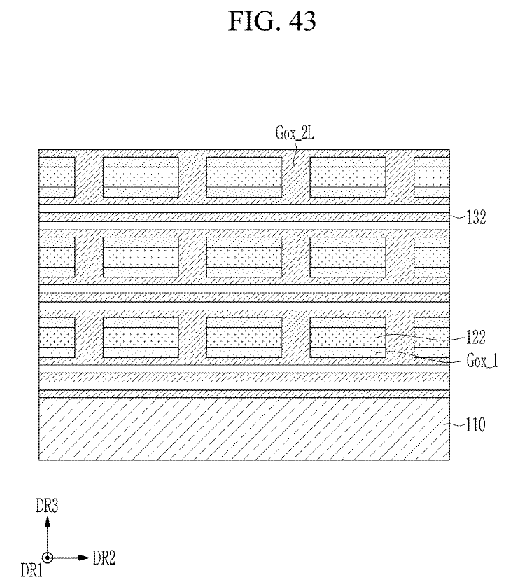

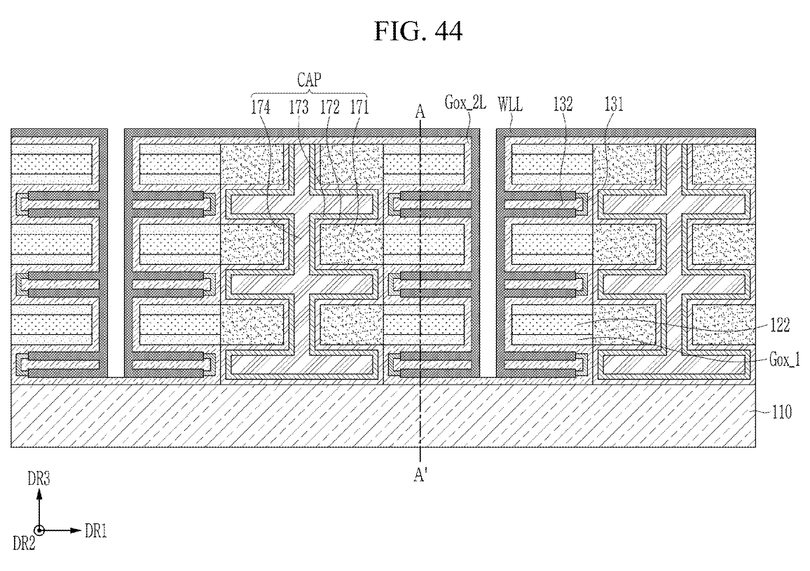

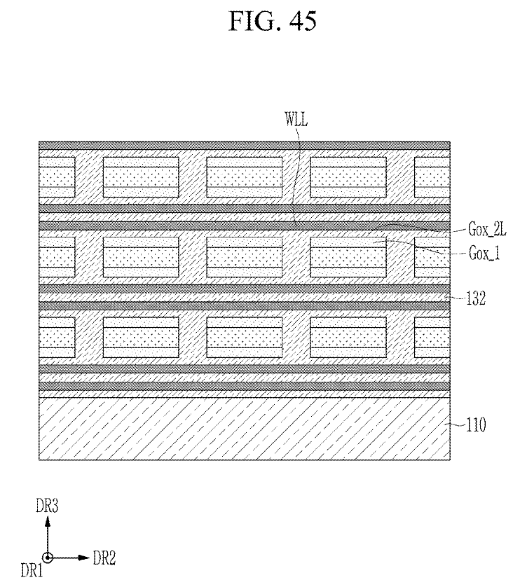

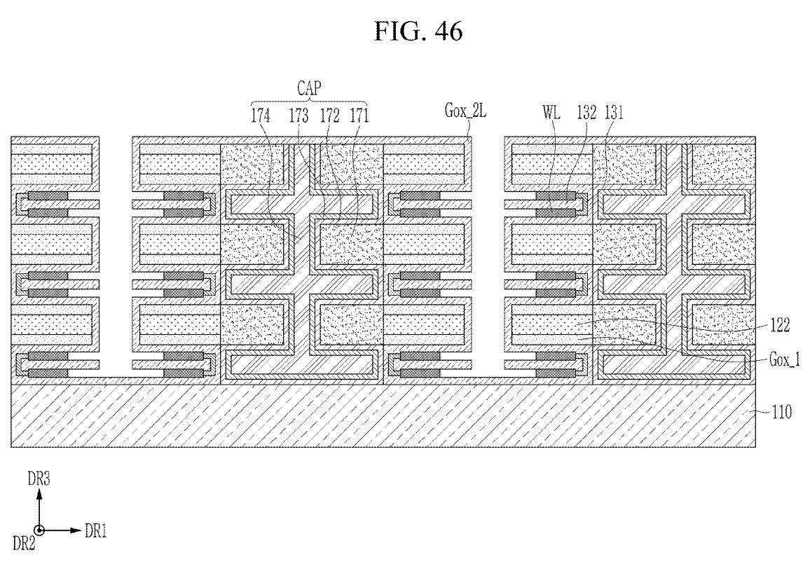

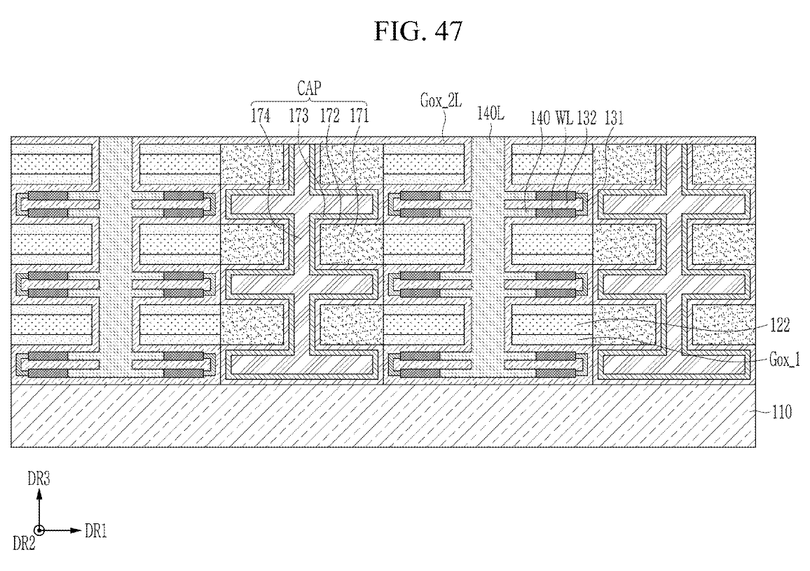

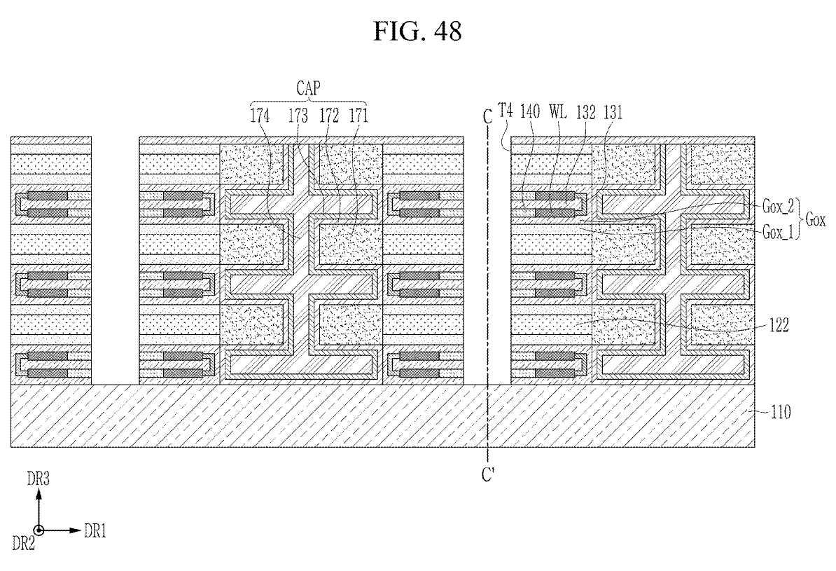

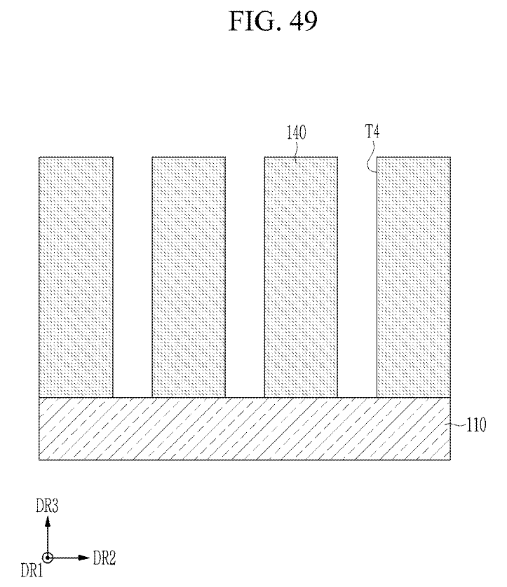

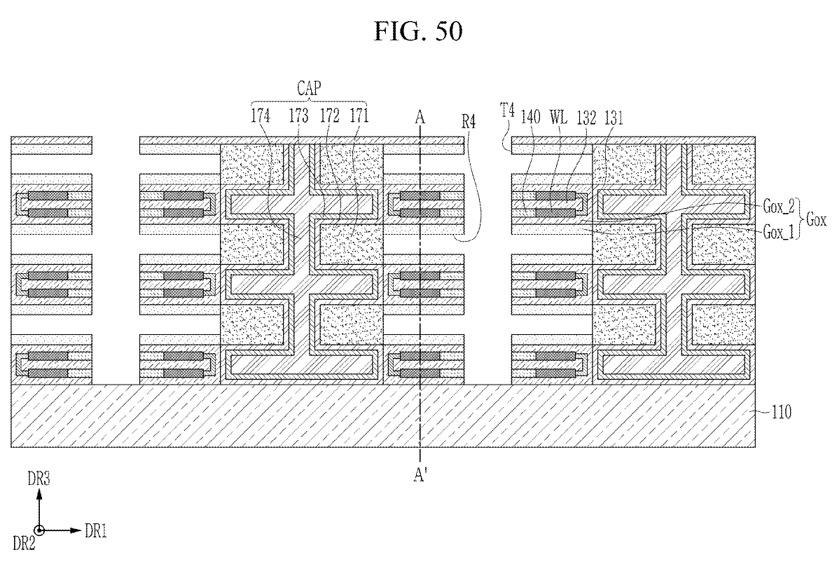

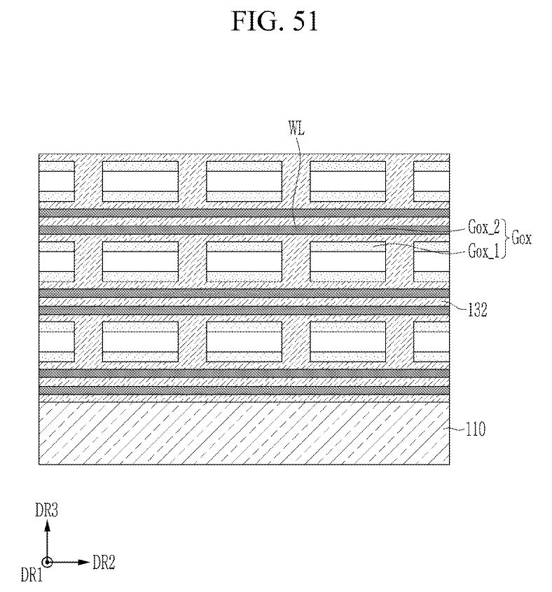

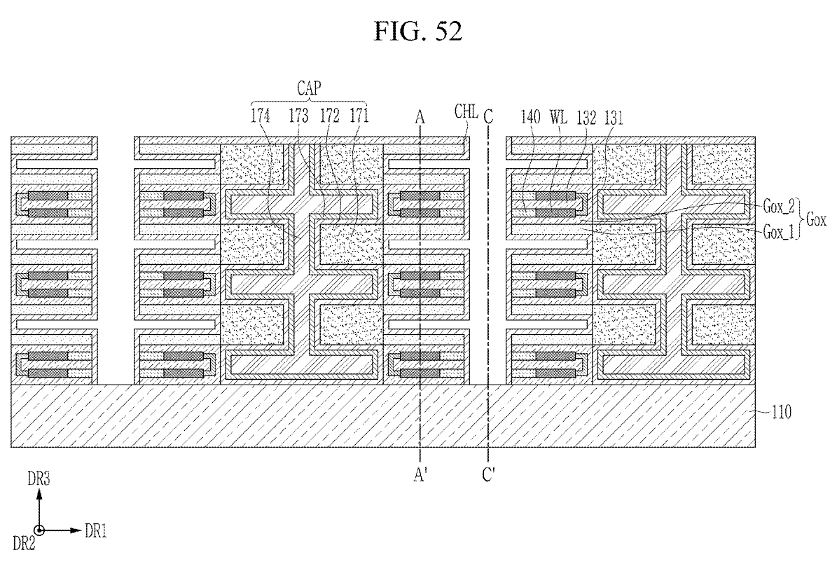

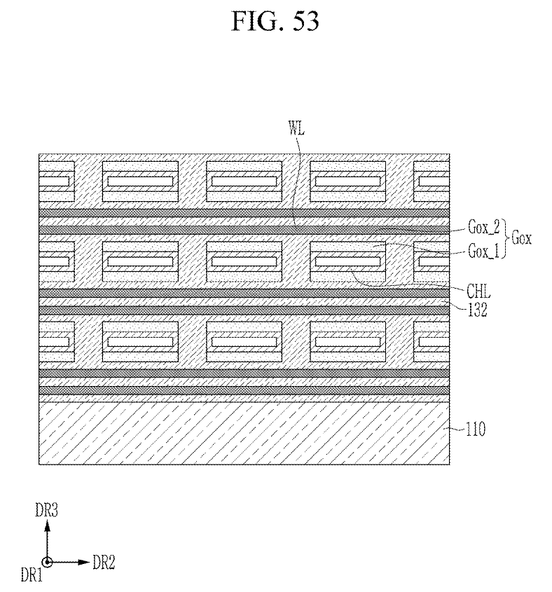

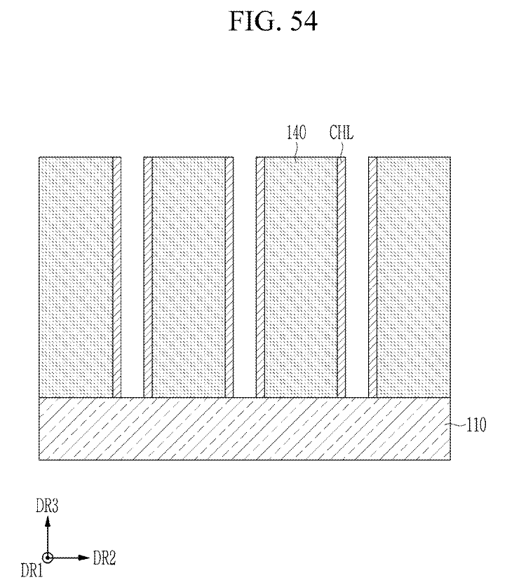

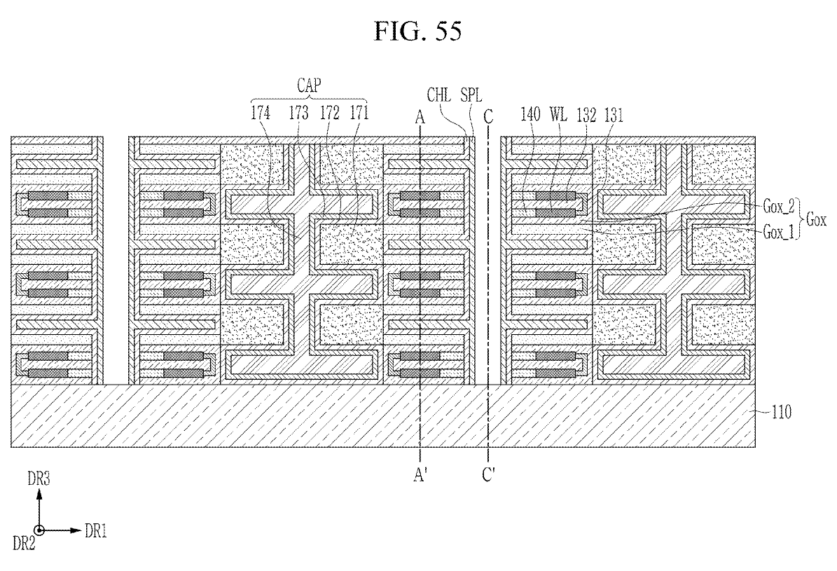

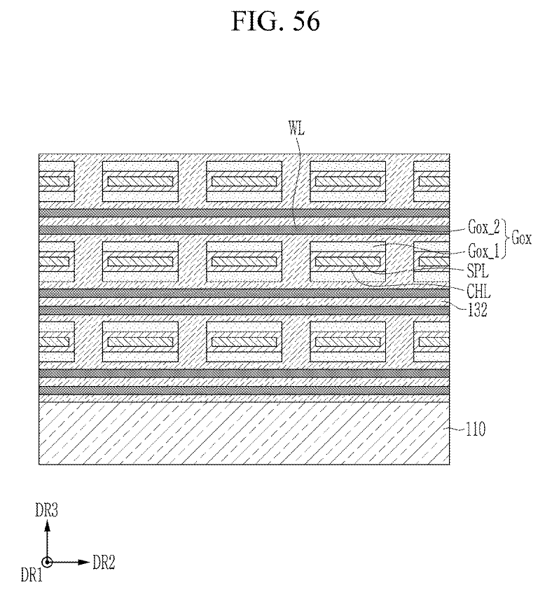

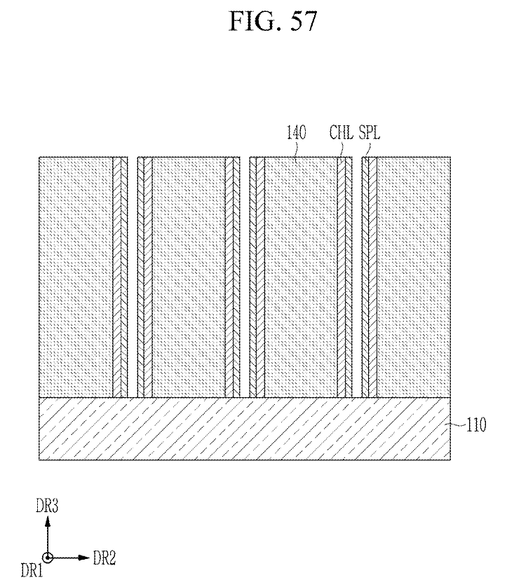

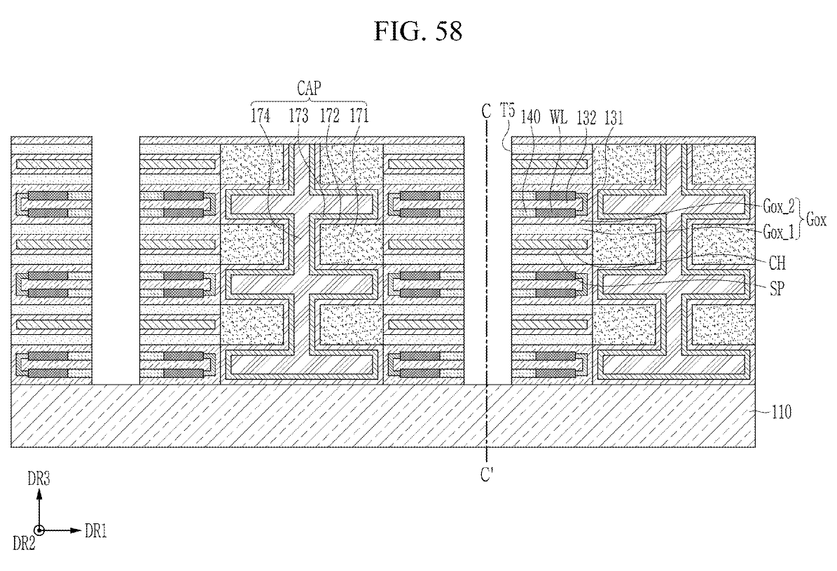

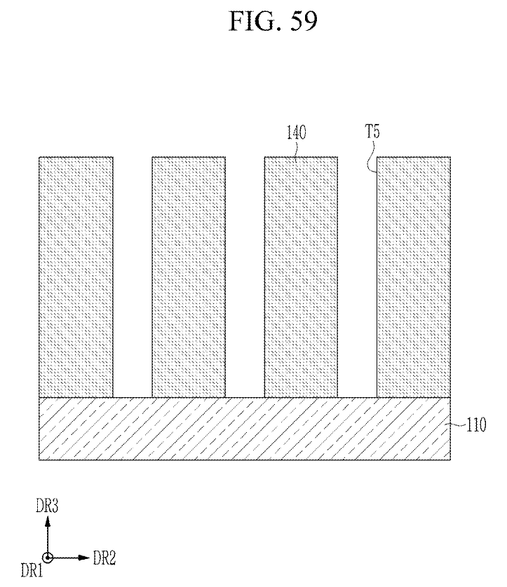

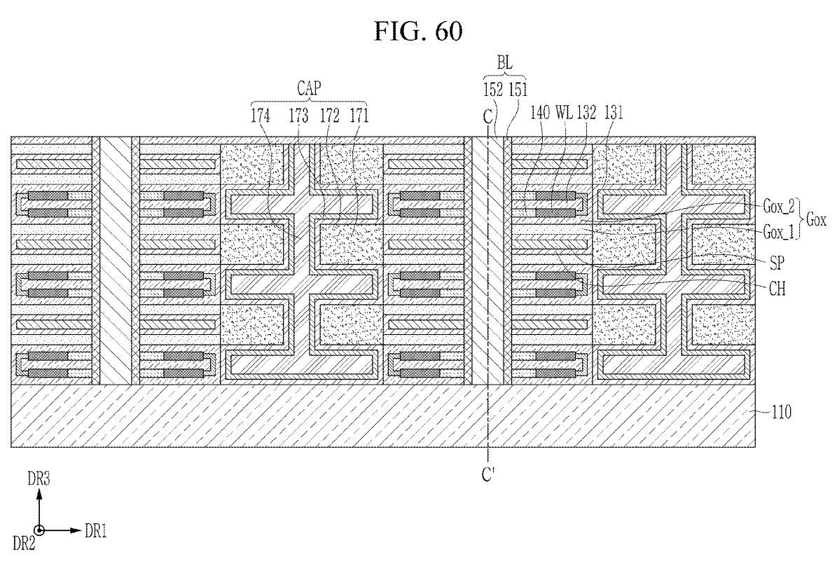

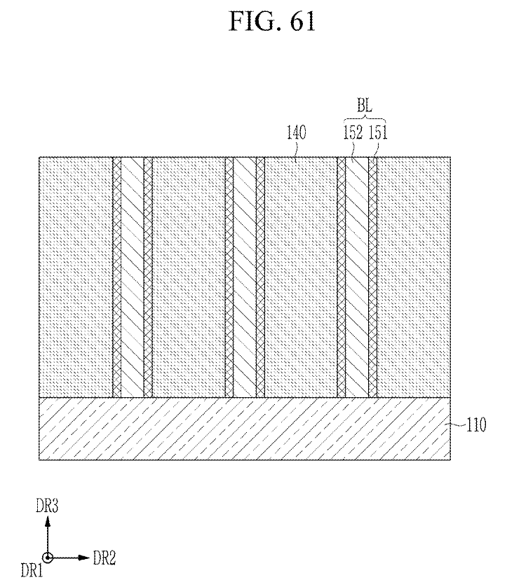

Hereinafter, the manufacturing method of the implementation shown in FIGS. 1 - 4 will be described with reference to FIGS. 9 - 61.

FIGS. 9 - 61 are cross-sectional views illustrating a method of manufacturing a semiconductor device according to some implementations.

FIG. 9, FIG. 12, FIG. 13, FIG. 14, FIG. 16, FIG. 18, FIG. 21, FIG. 22, FIG. 25, FIG. 27, FIG. 29, FIG. 31, FIG. 32, FIG. 34, FIG. 36, FIG. 38, FIG. 40, FIG. 42, FIG. 44, FIG. 46, FIG. 47, FIG. 48, FIG. 50, FIG. 52, FIG. 55, FIG. 58, and FIG. 60 are cross-sectional views along the first direction DR1 and the third direction DR3. FIG. 11, FIG. 15, FIG. 17, FIG. 19, FIG. 20, FIG. 23, FIG. 24, FIG. 26, FIG. 28, FIG. 30, FIG. 33, FIG. 35, FIG. 37, FIG. 39, FIG. 41, FIG. 43, FIG. 45, FIG. 49, FIG. 51, FIG. 53, FIG. 54, FIG. 56, FIG. 57, FIG. 59, and FIG. 61 are cross-sectional views along the second direction DR2 and the third direction DR3.

FIGS. 10 - 11 are cross-sectional views taken along the line A-A' of FIG. 9.

As shown in FIGS. 9 and 10, a plurality of sacrificial insulating material layers 121L and a plurality of sacrificial semiconductor material layers 122L may be alternately and repeatedly stacked on a substrate 110 in a third direction DR3 perpendicular to the upper surface of the substrate 110. The thickness of the sacrificial insulating material layer 121L in the third direction DR3 may be greater than the thickness of the sacrificial semiconductor material layer 122L in the third direction DR3.

The sacrificial insulating material layer 121L may include an insulating material. For example, the sacrificial insulating material layer 121L may include silicon nitride, but is not limited thereto. The sacrificial semiconductor material layer 122L may include a semiconductor material. For example, the sacrificial semiconductor material layer 122L may include silicon, but is not limited thereto. The sacrificial insulating material layer 121L may include a material having an etch selectivity with respect to the sacrificial semiconductor material layer 122L. Accordingly, in a subsequent process, the sacrificial insulating material layer 121L may be selectively removed.

In some implementations, a first gate insulating material layer Gox_1L may be positioned between the sacrificial insulating material layer 121L and the sacrificial semiconductor material layer 122L. For example, the sacrificial insulating material layer 121L, the first gate insulating material layer Gox_1L, the sacrificial semiconductor material layer 122L, the first gate insulating material layer Gox_1L, and the sacrificial insulating material layer 121L may be stacked in this order.

The first gate insulating material layer Gox_1L may include at least one of a high dielectric constant material, silicon oxide, silicon nitride, or silicon oxynitride. A high dielectric constant material may include at least one selected from hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

However, it is not limited to the above-described implementations. For example, the first gate insulating material layer Gox_1L may be omitted, and the sacrificial insulating material layer 121L, sacrificial semiconductor material layer 122L, sacrificial insulating material layer 121L, and sacrificial semiconductor material layer 122L may be sequentially stacked.

Subsequently, as shown in FIG. 11, a plurality of first isolation patterns ISO1 may be formed spaced apart and arranged along the second direction DR2.

First, the plurality of sacrificial insulating material layers 121L, the plurality of sacrificial semiconductor material layers 122L, and the plurality of first gate insulating material layers Gox_1L may be patterned to form a plurality of first isolation trenches. Each of the plurality of first isolation trenches may have a depth in the third direction DR3, and may extend along the first direction DR1. The plurality of sacrificial insulating material layers 121L, the plurality of sacrificial semiconductor material layers 122L, and the plurality of first gate insulating material layers Gox_1L may be separated in the second direction DR2 by the plurality of first isolation trenches. A plurality of preliminary sacrificial insulating layers 121P, a plurality of preliminary sacrificial semiconductor layers 122P, and a plurality of first preliminary gate insulating layers Gox_1P which are arranged spaced apart in the second direction DR2 by the plurality of first isolation trenches may be formed.

Subsequently, an insulation material may be filled in the plurality of first isolation trenches by a deposition process to form the plurality of first isolation patterns ISO1. The plurality of first isolation patterns ISO1 may be spaced apart and arranged in the second direction DR2. The plurality of first isolation patterns ISO1 may have a depth in the third direction DR3, and may extend along the first direction DR1. The first isolation pattern ISO1 may include the same insulating material as the preliminary sacrificial insulating layer 121P. For example, the first isolation pattern ISO1 and the preliminary sacrificial insulating layer 121P may include silicon nitride, but are not limited thereto.

As shown in FIG. 12, a plurality of second isolation patterns ISO2 spaced apart and arranged along the first direction DR1 may be formed.

First, the plurality of preliminary sacrificial insulating layers 121P, the plurality of preliminary sacrificial semiconductor layers 122P, and the plurality of first preliminary gate insulating layers Gox_1P may be patterned to form a plurality of second isolation trenches. Each of the plurality of second isolation trenches has a depth in the third direction DR3, and may extend along the second direction DR2. Each of the plurality of second isolation trenches may extend in the second direction DR2 while crossing the plurality of first isolation patterns ISO1 arranged spaced apart in the second direction DR2. The plurality of preliminary sacrificial insulating layers 121P, the plurality of preliminary sacrificial semiconductor layers 122P, and the plurality of first preliminary gate insulating layers Gox_1P may be separated in the first direction DR1 by the plurality of second isolation trenches. A plurality of sacrificial insulating layers 121, a plurality of sacrificial semiconductor layers 122, and a plurality of first gate insulating layers Gox_1 which are arranged spaced apart in the second direction DR2 by the plurality of second isolation trenches may be formed. The plurality of sacrificial insulating layers 121 may be spaced apart and arranged in the first direction DR1. The plurality of sacrificial semiconductor layers 122 may be spaced apart and arranged in a first direction DR1. The plurality of first gate insulating layers Gox_1 may be spaced apart and arranged in the first direction DR1.

Subsequently, through a deposition process, an insulating material may be filled into the plurality of second isolation trenches to form the plurality of second isolation patterns ISO2. The plurality of second isolation patterns ISO2 may be arranged spaced apart in the first direction DR1. The plurality of second isolation patterns ISO2 may have a depth in the third direction DR3, and may extend along the second direction DR2. The second isolation pattern ISO2 may include a different material from the first isolation pattern ISO1. For example, the first isolation pattern ISO1 may include silicon nitride, and the second isolation pattern ISO2 may include silicon oxide; however, it is not limited thereto. The insulating material included in each of the first isolation pattern ISO1 and the second isolation pattern ISO2 may be variously changed.

As illustrated in FIG. 13, a plurality of first trenches T1 may be formed by removing some of the plurality of second isolation patterns ISO2. Every other one of the plurality of second isolation patterns ISO2, which are spaced apart and arranged along the first direction DR1, may be removed. For example, the second isolation patterns ISO2 positioned at odd-numbered locations along the first direction DR1 may be removed. In another example, the second isolation patterns ISO2 positioned at even-numbered positions along the first direction DR1 may be removed.

First, a photoresist layer covering upper surfaces of the plurality of second isolation patterns ISO2 may be formed, and a photoresist pattern exposing upper surfaces of every other one of the plurality of second isolation patterns ISO2 to be removed may be formed through a photolithography process. An etching process may be performed using the photoresist pattern to remove the second isolation patterns ISO2 having an upper surface exposed. In the etching process, a material having a high etch selectivity for the second isolation pattern ISO2 with respect to the sacrificial insulating layer 121, the sacrificial semiconductor layer 122, the first gate insulating layer Gox_1, the substrate 110, and the first isolation pattern ISO1 may be used. The second isolation patterns ISO2 may be selectively removed by an etching process, and the plurality of first trenches T1 may be formed.

The plurality of first trenches T1 may be spaced apart and arranged along the first direction DR1. The second isolation pattern ISO2 may be positioned between first trenches T1 adjacent in the first direction DR1. The first trench T1 may be positioned between second isolation patterns ISO2 adjacent in the first direction DR1. Each of the plurality of first trenches T1 may extend in the second direction DR2. Each of the plurality of first trenches T1 may extend in the second direction DR2 crossing the plurality of first isolation patterns ISO1 arranged spaced apart in the second direction DR2.

The upper surface of the substrate 110 may be exposed by each of the plurality of first trenches T1. A side surface of each of the plurality of sacrificial insulating layers 121, each of the plurality of sacrificial semiconductor layers 122, and each of the plurality of first gate insulating layers Gox_1 in the first direction DR1, which are spaced apart and arranged in the third direction DR3, may be exposed by each of the plurality of first trenches T1.

FIG. 15 is a cross-sectional view taken along line B-B' of FIG. 14.

As shown in FIGS. 14 and 15, a plurality of first recesses R1 may be formed by removing a portion of each of a plurality of sacrificial insulating layers 121 through the plurality of first trenches T1.

For example, an etching process may be performed using a material having a high etch selectivity for the sacrificial insulating layer 121 with respect to the sacrificial semiconductor layer 122 and the first gate insulating layer Gox_1. A side surface of each of the plurality of sacrificial insulating layers 121 in the first direction DR1, which are spaced apart and arranged in the third direction DR3, may be exposed through the plurality of first trenches T1. The plurality of sacrificial insulating layers 121 may be etched in a side direction for example, the first direction DR1.

According to the foregoing, the first isolation pattern ISO1 may include the same material as the sacrificial insulating layer 121. A side surface of each of the plurality of first isolation patterns ISO1 in the first direction DR1, which are spaced apart in the second direction DR2, may be exposed through each of the plurality of first trenches T1. A portion of each of the plurality of first isolation patterns ISO1 may be etched together with a portion of each of the plurality of sacrificial insulating layers 121. The plurality of first isolation patterns ISO1 may be etched to the same depth as the plurality of sacrificial insulating layers 121 along the first direction DR1.

In a cross-section along the second direction DR2 and the third direction DR3 crossing the plurality of first recesses R1, the first gate insulating layer Gox_1 may be positioned on both side surfaces of each of the plurality of sacrificial semiconductor layers 122 in the third direction DR3. Each of both side surfaces of each of the plurality of sacrificial semiconductor layers 122 in the third direction DR3 may be covered by the first gate insulating layer Gox_1. Both side surfaces of each of the plurality of sacrificial semiconductor layers 122 in the second direction DR2 may be exposed. Both side surfaces of the sacrificial semiconductor layer 122 along the third direction DR3 may be the upper surface and the lower surface of the sacrificial semiconductor layer 122.

Side surfaces of a plurality of first gate insulating layers Gox_1 in the third direction DR3 may be exposed by the plurality of first recesses R1. The upper surface of the first gate insulating layer Gox_1 positioned on the upper surface of the sacrificial semiconductor layer 122 and the lower surface of the first gate insulating layer Gox_1 positioned on the lower surface of the sacrificial semiconductor layer 122 may be exposed by the plurality of first recesses R1.

FIG. 17 is a cross-sectional view taken along the line B-B' of FIG. 16.

As shown in FIGS. 16 and 17, a first sacrificial layer 161L may be formed in the plurality of first trenches T1 and the plurality of first recesses R1. For example, the first sacrificial layer 161L covering the inner surface of each of the plurality of first trenches T1 and the inner surface of each of the plurality of first recesses R1 may be formed by a deposition process. The first sacrificial layer 161L may cover the inner surface of each of the plurality of first trenches T1 and the inner surface of each of the plurality of first recesses R1 with a uniform thickness. The first sacrificial layer 161L may cover a side surface of each of the plurality of first sacrificial semiconductor layers 122 in the first direction DR1, and a side surface of each of the plurality of first gate insulating layers Gox_1 in the first direction DR1. The first sacrificial layer 161L may cover a side surface of each of the plurality of sacrificial insulating layers 121 in the first direction DR1, and a side surface of each of the plurality of first gate insulating layers Gox_1 in the third direction DR3. The first sacrificial layer 161L may further cover the upper surface of the substrate 110. The first sacrificial layer 161L may further cover the upper surfaces of the second isolation patterns ISO2 among the plurality of second isolation patterns ISO2 that remain without being removed.

In a cross-section along the second direction DR2 and the third direction DR3 crossing the plurality of first recesses R1, the first sacrificial layer 161L may surround each of the plurality of sacrificial semiconductor layers 122. The first sacrificial layer 161L may cover both side surfaces of each of the plurality of sacrificial semiconductor layers 122 in the second direction DR2 and the third direction DR3. The first gate insulating layer Gox_1 may be positioned between the first sacrificial layer 161L and the side surface of each of the plurality of sacrificial semiconductor layers 122 in the third direction DR3. The first sacrificial layer 161L may extend in the second direction DR2. For example, as the interval between the plurality of sacrificial semiconductor layers 122 arranged spaced apart in the second direction DR2 is less than or equal to a threshold value, the space between the plurality of sacrificial semiconductor layers 122 arranged spaced apart in the second direction DR2 may be filled with the first sacrificial layer 161L. As the interval between the plurality of sacrificial semiconductor layers 122 spaced apart and arranged in the third direction DR3 exceeds the threshold value, a portion of the space between the plurality of sacrificial semiconductor layers 122 spaced apart and arranged in the third direction DR3 may remain unfilled by the first sacrificial layer 161L.

The first sacrificial layer 161L may include an insulating material. For example, the first sacrificial layer 161L may include silicon nitride, but is not limited thereto.

FIG. 19 is a cross-sectional view taken along the line B-B' of FIG. 18.

As shown in FIGS. 18 and 19, a second sacrificial pattern 162 may be formed on the first sacrificial layer 161L. For example, the first sacrificial layer 161L is formed in the plurality of first recesses R1 by a deposition process, after which a second sacrificial layer that fills the remaining space is formed. Then, a portion of the second sacrificial layer is removed by an etch-back process, whereby the second sacrificial pattern 162 may be formed. The second sacrificial pattern 162 may be positioned in the plurality of first recesses R1. A side surface of the second sacrificial pattern 162 in the first direction DR1 adjacent to the first trench T1 may be spaced farther from the center of the first trench T1 than a side surface of each of the plurality of sacrificial semiconductor layers 122 in the first direction DR1 adjacent to the first trench T1.

In a cross-section along the second direction DR2 and the third direction DR3 crossing the plurality of first recesses R1, the second sacrificial pattern 162 may fill a remaining space that is not filled by the first sacrificial layer 161L formed between the plurality of sacrificial semiconductor layers 122 spaced apart and arranged in the third direction DR3.

The second sacrificial pattern 162 may include an insulating material. The second sacrificial pattern 162 may include a material having an etch selectivity with respect to the first sacrificial layer 161L. For example, the first sacrificial layer 161L may include silicon nitride, and the second sacrificial pattern 162 may include silicon oxide, but is not limited thereto.

As shown in FIG. 20, a third sacrificial layer 163L may be formed on the first sacrificial layer 161L and the second sacrificial pattern 162. For example, the third sacrificial layer 163L covering the first sacrificial layer 161L and the second sacrificial pattern 162 with a uniform thickness may be formed by a deposition process. The third sacrificial layer 163L may cover portions of the first sacrificial layer 161L that are positioned on a side surface of each of the plurality of first sacrificial semiconductor layers 122 in the first direction DR1 and on a side surface of each of the plurality of first gate insulating layers Gox_1 in the first direction DR1. The third sacrificial layer 163L may cover a portion of the first sacrificial layer 161L covering an upper surface of the substrate 110. The third sacrificial layer 163L may cover a portion of the first sacrificial layer 161L that covers the upper surfaces of the second isolation patterns ISO2 among the plurality of second isolation patterns ISO2 that remain without being removed. The third sacrificial layer 163L may cover the entire second sacrificial pattern 162.

The third sacrificial layer 163L may include an insulating material. For example, the third sacrificial layer 163L may include silicon nitride, but is not limited thereto. For example, the third sacrificial layer 163L may include the same insulating material as the first sacrificial layer 161L, but is not limited thereto.

FIG. 22 is a cross-sectional view taken along line B-B' of FIG. 21.

As illustrated in FIG. 21 and FIG. 22, a plurality of second trenches T2 may be formed to expose a side surface of each of the plurality of sacrificial semiconductor layers 122 in the first direction DR1 and a side surface of each of the plurality of first gate insulating layers Gox_1 in the first direction DR1.

First, a photoresist layer covering the upper surfaces of the first sacrificial layer 161L and the third sacrificial layer 163L positioned on the upper surfaces of the plurality of second isolation patterns ISO2 that remain and are not removed among the plurality of second isolation patterns ISO2 is formed, and a photoresist pattern exposing portions of the first sacrificial layer 161L and the third sacrificial layer 163L to be removed may be formed through a photolithography process. An etch process may be performed using the photoresist pattern to remove portions of the first sacrificial layer 161L and the third sacrificial layer 163L. Portions of the first sacrificial layer 161L and the third sacrificial layer 163L that cover a side surface of each of the plurality of sacrificial semiconductor layers 122 in the first direction DR1 and a side surface of each of the plurality of first gate insulating layers Gox_1 in the first direction DR1 are removed by an etch process, and the plurality of second trenches T2 may be formed. Portions of the third sacrificial layer 163L covering the upper surface of the substrate 110 may be removed by the etch process; however, portions of the first sacrificial layer 161L covering the upper surface of the substrate 110 may not be completely removed and may partially remain. The upper surface of the substrate 110 may not be exposed by an etch process for forming the plurality of second trenches T2.

A portion of the third sacrificial layer 163L covering the second sacrificial pattern 162 may be stepped in the first direction DR1 with respect to portions of the first sacrificial layer 161L and the third sacrificial layer 163L covering a side surface of each of the plurality of sacrificial semiconductor layers 122 in the first direction DR1 and a side surface of each of the plurality of first gate insulating layers Gox_1 in the first direction DR1. Accordingly, since the portion of the third sacrificial layer 163L covering the second sacrificial pattern 162 is not removed in the etch process, the second sacrificial pattern 162 also may not be removed.

Portions of the first sacrificial layer 161L and the third sacrificial layer 163L remaining after the etching process may be referred to as the first sacrificial pattern 161 and the third sacrificial pattern 163, respectively.

Subsequently, a portion of each of the plurality of first gate insulating layers Gox_1 may be removed through the plurality of second trenches T2.

For example, an etch process may be performed using a material having a high etch selectivity for the first gate insulating layer Gox_1 with respect to the sacrificial semiconductor layer 122, the first sacrificial pattern 161, and the third sacrificial pattern 163. The plurality of first gate insulating layers Gox_1 may be selectively etched by an etch process, and the plurality of sacrificial semiconductor layers 122, the first sacrificial pattern 161, and the third sacrificial pattern 163 may be scarcely etched. A side surface of each of the plurality of first gate insulating layers Gox_1, in the first direction DR1, which are spaced apart and arranged in the third direction DR3, may be exposed through a plurality of second trenches T2. The plurality of first gate insulating layers Gox_1 may be etched in the side direction for example, the first direction DR1.

In a cross-section along the second direction DR2 and the third direction DR3, the plurality of first gate insulating layers Gox_1 positioned on both side surfaces of each plurality of sacrificial semiconductor layers 122 in the third direction DR3 may be removed. As the plurality of first gate insulating layers Gox_1 are removed, both side surfaces of each plurality of sacrificial semiconductor layers 122 in the third direction DR3 may be exposed.

FIG. 24 is a cross-sectional view taken along line B-B' of FIG. 22.

As shown in FIGS. 23 and 24, as the plurality of first gate insulating layers Gox_1 are removed, a portion of each of the exposed plurality of sacrificial semiconductor layers 122 may be removed.

For example, an etch process may be performed using a material having a high etch selectivity for the sacrificial semiconductor layer 122 with respect to the first gate insulating layer Gox_1, the first sacrificial pattern 161, and the third sacrificial pattern 163. The plurality of sacrificial semiconductor layers 122 may be selectively etched by an etch process, and the plurality of first gate insulating layers Gox_1, the first sacrificial pattern 161, and the third sacrificial pattern 163 may be hardly etched. The plurality of sacrificial semiconductor layers 122 may be etched in a side direction for example, the first direction DR1. The plurality of sacrificial semiconductor layers 122 may be etched to the same depth as the plurality of first gate insulating layers Gox_1 along the first direction DR1.

In the cross-section along the second direction DR2 and the third direction DR3, as the plurality of sacrificial semiconductor layers 122 are removed, a plurality of empty spaces surrounded by the first sacrificial pattern 161 may be formed. The plurality of empty spaces may be spaced apart and arranged in the second direction DR2 and the third direction DR3.

FIG. 26 is a cross-sectional view taken along line B-B' of FIG. 25.

As shown in FIGS. 25 and 26, a plurality of first capacitor electrodes 171 may be formed on a side surface of each of a plurality of first gate insulating layers Gox_1 and a plurality of sacrificial semiconductor layers 122 in the first direction DR1. For example, the plurality of first capacitor electrodes 171 may be formed through a deposition process.

Each of the plurality of first capacitor electrodes 171 may cover a side surface, in the first direction DR1, of each of the two first gate insulating layers Gox_1 positioned on both side surfaces of the sacrificial semiconductor layer 122 and the sacrificial semiconductor layer 122 in the third direction DR3. The plurality of first capacitor electrodes 171 may cover surfaces of the first sacrificial pattern 161 that are spaced apart in the third direction DR3. The length of each of the plurality of first capacitor electrodes 171 in the first direction DR1 may be the same as the length of the first sacrificial pattern 161 in the first direction DR1.

In the cross-section along the second direction DR2 and the third direction DR3, the plurality of first capacitor electrodes 171 may respectively fill the plurality of empty spaces surrounded by the first sacrificial pattern 161.

FIG. 28 is a cross-sectional view taken along the line B-B' of FIG. 27.

As shown in FIG. 27 and FIG. 28, the first sacrificial pattern 161, the second sacrificial pattern 162, and the third sacrificial pattern 163 may be removed.

For example, an etching process may be performed using a material having a high etch selectivity for the first sacrificial pattern 161, the second sacrificial pattern 162, and the third sacrificial pattern 163 with respect to the first capacitor electrode 171 and the substrate 110. By an etch process, the first sacrificial pattern 161, the second sacrificial pattern 162, and the third sacrificial pattern 163 may be selectively etched, and the plurality of first capacitor electrodes 171 and the substrate 110 may be scarcely etched.

As the first sacrificial pattern 161, the second sacrificial pattern 162, and the third sacrificial pattern 163 are removed, both side surfaces of the plurality of first capacitor electrodes 171 in the third direction DR3 and the second direction DR2 may be exposed.

For example, the etch process may be carried out for a predetermined time and may be stopped. For example, the etch process may proceed until a side surface of the sacrificial insulating layer 121 in the first direction DR1 is exposed, and may be stopped.

FIG. 30 is a cross-sectional view taken along the A-A' line of FIG. 29.

As shown in FIGS. 29 and 30, a dielectric layer 172, a second capacitor electrode 173, and a plate electrode 174 may be sequentially formed on the plurality of first capacitor electrodes 171. For example, the dielectric layer 172, the second capacitor electrode 173, and the plate electrode 174 may be formed through a deposition process.

First, a dielectric layer 172 may be formed on the plurality of first capacitor electrodes 171. The dielectric layer 172 may cover the plurality of first capacitor electrodes 171 spaced apart and arranged in the third direction DR3. The dielectric layer 172 may cover a pair of first capacitor electrodes 171 spaced apart in the first direction DR1. The pair of first capacitor electrodes 171 spaced apart in the first direction DR1 may be positioned between adjacent second isolation patterns ISO2. A bit line BL may be formed in a region corresponding to the second isolation patterns ISO2 in a subsequent process. The dielectric layer 172 may cover the exposed surfaces of the plurality of first capacitor electrodes 171 with a uniform thickness. The dielectric layer 172 may further cover an exposed side surface of each of the plurality of sacrificial insulating layers 121 in the first direction DR1. The dielectric layer 172 may further cover an exposed upper surface of the substrate 110.

Subsequently, the second capacitor electrode 173 may be formed on the dielectric layer 172. The second capacitor electrode 173 may cover the surface of the dielectric layer 172 with a uniform thickness. The second capacitor electrode 173 may be spaced apart from the plurality of first capacitor electrodes 171 by the dielectric layer 172.

Subsequently, the plate electrode 174 may be formed on the second capacitor electrode 173. The plate electrode 174 may fill a remaining space in which the dielectric layer 172 and the second capacitor electrode 173 are formed on the plurality of pairs of first capacitor electrode 171 arranged spaced apart in the third direction DR3.

The first capacitor electrode 171, dielectric layer 172, second capacitor electrode 173, and plate electrode 174 may form the capacitor CAP.

In a cross-section along the second direction DR2 and the third direction DR3 of the region positioned between the capacitor CAP and the second isolation pattern ISO2, the plurality of first isolation patterns ISO1 may be spaced apart and arranged in the second direction DR2.

As shown in FIG. 31, the second isolation patterns ISO2 may be removed to form a plurality of third trenches T3. The second isolation patterns ISO2 removed in this process may be the second isolation patterns ISO2 remaining after some of the plurality of second isolation patterns ISO2 are removed in the process of FIG. 13. The second isolation patterns ISO2 positioned at both sides of the plurality of capacitors CAP in the first direction DR1 may be removed. The dielectric layer 172, the second capacitor electrode 173, and the plate electrode 174 of the respective capacitors CAP are connected to one another. The second isolation patterns ISO2 positioned between the capacitors CAP spaced apart in the first direction DR1 may be removed.

First, a photoresist layer covering the upper surface of the second isolation patterns ISO2 may be formed, and a photoresist pattern exposing the upper surface of the second isolation patterns ISO2 may be formed through a photolithography process. An etch process may be carried out using the photoresist pattern to remove the second isolation patterns ISO2 having upper surfaces exposed. In the etching process, a material having a high etch selectivity for the second isolation pattern ISO2 with respect to the sacrificial insulating layer 121, the sacrificial semiconductor layer 122, the first gate insulating layer Gox_1, the substrate 110, and the first isolation pattern ISO1 may be used. The second isolation patterns ISO2 may be selectively removed by an etch process, and the plurality of third trenches T3 may be formed.

The plurality of third trenches T3 may be spaced apart and arranged along the first direction DR1. The plurality of capacitors CAP may be positioned between the third trenches T3 adjacent in the first direction DR1. Third trenches T3 may be positioned between capacitors CAP spaced apart in the first direction DR1. Each of the plurality of third trenches T3 may extend in the second direction DR2. Each of the plurality of third trenches T3 may cross the plurality of first isolation patterns ISO1 spaced apart and arranged in the second direction DR2, and may extend in the second direction DR2.

By each of the plurality of third trenches T3, an upper surface of the substrate 110 may be exposed. A side surface of each of the plurality of sacrificial insulating layers 121, each of the plurality of sacrificial semiconductor layers 122, and each of the plurality of first gate insulating layers Gox_1 in the first direction DR1, which are arranged spaced apart in the third direction DR3, may be exposed by each of the plurality of third trenches T3. The other side surface of each of the plurality of sacrificial insulating layers 121, each of the plurality of sacrificial semiconductor layers 122, and each of the plurality of first gate insulating layers Gox_1 in the first direction DR1 may be covered by the plurality of capacitors CAP.

FIG. 33 is a cross-sectional view taken along line A-A' of FIG. 32.

As shown in FIGS. 32 and 33, the plurality of sacrificial insulating layers 121 may be removed through the plurality of third trenches T3 to form a plurality of second recesses R2.

For example, an etch process may be performed using a material having a high etch selectivity for the sacrificial insulating layer 121 with respect to the sacrificial semiconductor layer 122 and the first gate insulating layer Gox_1. A side surface of each of the plurality of sacrificial insulating layers 121 in the first direction DR1, which are spaced apart and arranged in the third direction DR3, may be exposed through the plurality of third trenches T3. The plurality of sacrificial insulating layers 121 may be etched in a side direction for example, the first direction DR1.

According to the above, the first isolation pattern ISO1 may include the same material as the sacrificial insulating layer 121. A side surface of each of the plurality of first isolation patterns ISO1 in the first direction DR1, which are spaced apart and arranged in the second direction DR2, may be exposed through each of the plurality of third trenches T3. Each of the plurality of first isolation patterns ISO1 may be etched together with each of the plurality of sacrificial insulating layers 121.

In a cross-section along the second direction DR2 and the third direction DR3 crossing the plurality of second recesses R2, the first gate insulating layer Gox_1 may be positioned on both side surfaces of each of the plurality of sacrificial semiconductor layers 122 in the third direction DR3, and each of both side surfaces of each of the plurality of sacrificial semiconductor layers 122 in the third direction DR3 may be covered by the first gate insulating layer Gox_1. Both side surfaces of each of the plurality of sacrificial semiconductor layers 122 in the second direction DR2 may be exposed. Both side surfaces of the sacrificial semiconductor layer 122 in the third direction DR3 may be the upper surface and the lower surface of the sacrificial semiconductor layer 122.

A side surface of each of the plurality of first gate insulating layers Gox_1 in the third direction DR3 may be exposed by the plurality of second recesses R2. The upper surface of the first gate insulating layer Gox_1 positioned on the upper surface of the sacrificial semiconductor layer 122 and the lower surface of the first gate insulating layer Gox_1 positioned on the lower surface of the sacrificial semiconductor layer 122 may be exposed by the plurality of first recesses R2.

FIG. 35 is a cross-sectional view taken along line A-A' of FIG. 34.

As shown in FIG. 34 and FIG. 35, a second gate insulating material layer Gox_2L may be formed in the plurality of third trenches T3 and the plurality of second recesses R2. For example, the second gate insulating material layer Gox_2L may be formed to cover the inner surface of each of the plurality of third trenches T3 and the inner surface of each of the plurality of second recesses R2 through a deposition process. The second gate insulating material layer Gox_2L may cover the inner surface of each of the plurality of third trenches T3 and the inner surface of each of the plurality of second recesses R2 with a uniform thickness. The second gate insulating material layer Gox_2L may cover a side surface of each of the plurality of first sacrificial semiconductor layers 122 in the first direction DR1, and a side surface of each of the plurality of first gate insulating layers Gox_1 in the first direction DR1. The second gate insulating material layer Gox_2L may cover a side surface of each of the plurality of capacitors CAP in the first direction DR1, and a side surface of each of the plurality of first gate insulating layers Gox_1 in the third direction DR3. The second gate insulating material layer Gox_2L may further cover the upper surface of the substrate 110.

In a cross-section along the second direction DR2 and the third direction DR3 crossing the plurality of second recesses R2, the second gate insulating material layer Gox_2L may surround each of the plurality of sacrificial semiconductor layers 122. The second gate insulating material layer Gox_2L may cover both side surfaces of each of the plurality of sacrificial semiconductor layers 122 in the second direction DR2 and the third direction DR3. The first gate insulating layer Gox_1 may be positioned between the second gate insulating material layer Gox_2L and side surfaces of each plurality of sacrificial semiconductor layers 122 in the third direction DR3. The second gate insulating material layer Gox_2L may extend in the second direction DR2. For example, as the interval w between the plurality of sacrificial semiconductor layers 122 spaced apart and arranged in the second direction DR2 is less than or equal to a threshold value, the space between the plurality of sacrificial semiconductor layers 122 spaced apart and arranged in the second direction DR2 may be filled with the second gate insulating material layer Gox_2L. However, the implementation is not limited thereto, and in another example, as the interval w between the plurality of sacrificial semiconductor layers 122 spaced apart and arranged in the second direction DR2 exceeds the threshold value, the space between the plurality of sacrificial semiconductor layers 122 spaced apart and arranged in the second direction DR2 may remain unfilled by the second gate insulating material layer Gox_2L. In this case, in a subsequent process, a word line WL may be filled in the space between the plurality of sacrificial semiconductor layers 122 arranged spaced apart in the second direction DR2. In addition, when the sacrificial semiconductor layer 122 is replaced with the channel pattern CH in a subsequent process, as shown in FIG. 3, the word line WL may surround both side surfaces of the plurality of channel patterns CH, which are spaced apart and arranged in the second direction DR2, in the third direction DR3 and the second direction DR2.

As the interval between the plurality of sacrificial semiconductor layers 122 spaced apart and arranged in the third direction DR3 exceeds the threshold value, a portion of the space between the plurality of sacrificial semiconductor layers 122 spaced apart and arranged in the third direction DR3 may remain unfilled by the second gate insulating material layer Gox_2L.

The second gate insulating material layer Gox_2L may include at least one of a high dielectric constant material, silicon oxide, silicon nitride, or silicon oxynitride. A high dielectric constant material may include at least one selected from the group consisting of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

FIG. 37 is a cross-sectional view taken along line A-A' of FIG. 36.

As shown in FIG. 36 and FIG. 37, a first insulating layer 131L may be formed on the second gate insulating material layer Gox_2L. For example, the first insulating layer 131L covering the surface of the second gate insulating material layer Gox_2L with a uniform thickness may be formed through a deposition process.

The first insulating layer 131L may include an insulating material. The first insulating layer 131L may include a material having an etch selectivity with respect to the second gate insulating material layer Gox_2L. For example, the second gate insulating material layer Gox_2L includes silicon oxide, and the first insulating layer 131L may include silicon oxide, but is not limited thereto.

FIG. 39 is a cross-sectional view taken along the A-A' line of FIG. 38.

As shown in FIGS. 38 and 39, a second preliminary insulating pattern 132P may be formed on the first insulating layer 131L. For example, a second insulating layer which fills a remaining space after forming the second gate insulating material layer Gox_2L and the first insulating layer 131L in the plurality of second recesses R2 through a deposition process, may be formed, and a portion of the second insulating layer may be removed through an etch-back process to form the second preliminary insulating pattern 132P. The second preliminary insulating pattern 132P may be positioned in the plurality of second recesses R2.

In a cross-section along the second direction DR2 and the third direction DR3 crossing the plurality of second recesses R2, the second preliminary insulating pattern 132P may fill the remaining space after the second gate insulating material layer Gox_2L and a first insulating layer 131L are formed in the spaces between the plurality of sacrificial semiconductor layers 122 that are spaced apart and arranged in the third direction DR3.

The second preliminary insulating pattern 132P may include an insulating material. The second preliminary insulating pattern 132P may include a material having an etch selectivity with respect to the first insulating layer 131L. For example, the first insulating layer 131L may include silicon nitride, and the second preliminary insulating pattern 132P may include silicon oxide, but is not limited thereto.

FIG. 41 is a cross-sectional view taken along the line A-A' of FIG. 40.

As shown in FIG. 40 and FIG. 41, a portion of the first insulating layer 131L may be removed to form a plurality of third recesses R3.

For example, an etch process may be performed using a material having a high etch selectivity for the first insulating layer 131L with respect to the second gate insulating material layer Gox_2L and the second preliminary insulating pattern 132P. The first insulating layer 131L may be selectively etched by the etch process, and the second gate insulating material layer Gox_2L and the second preliminary insulating pattern 132P may be scarcely etched. As a portion of the first insulating layer 131L positioned between the second gate insulating material layer Gox_2L and the second preliminary insulating pattern 132P is removed, the plurality of third recesses R3 may be formed. Surfaces of the second gate insulating material layer Gox_2L and the second preliminary insulating pattern 132P facing each other in the third direction DR3 may be exposed through the plurality of third recesses R3.

Portions of the first insulating layer 131L remaining after the etch process may be referred to as the first insulating pattern 131. The first insulating pattern 131 may cover surfaces of the second gate insulating material layer Gox_2L and the second preliminary insulating pattern 132P that face each other in the first direction DR1. The first insulating pattern 131 may further cover a portion of surfaces of the second gate insulating material layer Gox_2L and the second preliminary insulating pattern 132P facing each other in the third direction DR3.

FIG. 43 is a cross-sectional view taken along line A-A' of FIG. 42.

As illustrated in FIG. 42 and FIG. 43, portions of the second gate insulating material layer Gox_2L and the second preliminary insulating pattern 132P may be removed to increase the width in the third direction DR3 of each of the plurality of third recesses R3.

For example, an etch process may be performed using a material having a high etch selectivity for the second gate insulating material layer Gox_2L and the second preliminary insulating pattern 132P with respect to the first insulating pattern 131. The second gate insulating material layer Gox_2L and the second preliminary insulating pattern 132P may be selectively etched by an etch process, and the first insulating pattern 131 may be scarcely etched. As portions of the second gate insulating material layer Gox_2L and the second preliminary insulating pattern 132P are removed, the thicknesses of the exposed portions of the second gate insulating material layer Gox_2L and the second preliminary insulating pattern 132P may be overall reduced. Accordingly, a width of each of the plurality of third recesses R3 in the third direction DR3 may increase.

Portions of the second preliminary insulating pattern 132P remaining after the etch process may be referred to as the second insulating pattern 132.

FIG. 45 is a cross-sectional view taken along the A-A' line of FIG. 44.

As illustrated in FIGS. 44 and 45, a word line material layer WLL may be formed on the second gate insulating material layer Gox_2L, the first insulating pattern 131, and the second insulating pattern 132.

For example, through a deposition process, the word line material layer WLL may fill the plurality of third recesses R3. The word line material layer WLL may cover a side surface of the first insulating pattern 131 along the first direction DR1, and may cover the surfaces of the second gate insulating material layer Gox_2L and the second insulating pattern 132 facing each other in the third direction DR3. The word line material layer WLL may further cover a side surface of the second gate insulating material layer Gox_2L in the first direction DR1, which is positioned on side surfaces of the plurality of sacrificial semiconductor layers 122 and the plurality of first gate insulating layers Gox_1 in the first direction DR1.

In a cross-section along the second direction DR2 and the third direction DR3, the word line material layer WLL may extend in the second direction DR2 on both side surfaces of the plurality of sacrificial semiconductor layers 122 in the third direction DR3.

The word line material layer WLL may include a conductive material. For example, the word line material layer WLL may include a doped semiconductor material such as doped silicon or doped germanium, a conductive metal nitride such as titanium nitride or tantalum nitride, a metal such as tungsten, titanium, or tantalum, a metal-semiconductor compound such as tungsten silicide, cobalt silicide, or titanium silicide, or a combination thereof.

As shown in FIG. 46, a plurality of word lines WL may be formed by removing a portion of the word line material layer WLL.

For example, a portion of the word line material layer WLL may be removed through an etch-back process. Portions of the word line material layer WLL on side surfaces of the plurality of sacrificial semiconductor layers 122 and the plurality of first gate insulating layers Gox_1 in the first direction DR1 may be removed. Portions of the word line material layer WLL positioned between surfaces of the second gate insulating material layer Gox_2L and the second insulating pattern 132 facing each other in the third direction DR3 may be removed. Portions of the word line material layer WLL positioned between surfaces of the second gate insulating material layer Gox_2L and the second insulating pattern 132 facing each other in the third direction DR3 may remain partially and not be completely removed. Portions of the word line material layer WLL remaining between the surfaces of the second gate insulating material layer Gox_2L and the second insulating pattern 132 facing each other in the third direction DR3 may be respectively referred to as word lines WL.

The plurality of word lines WL may be spaced apart and arranged in the third direction DR3 with the second insulating pattern 132 interposed therebetween. In some implementations, the plurality of word lines WL may be disposed spaced apart from each other in the third direction DR3 with the sacrificial semiconductor layer 122 interposed therebetween, but is not limited thereto. For example, the word line WL may surround the sacrificial semiconductor layer 122 in the second direction DR2 and the third direction DR3.

As illustrated in FIG. 47, a third insulating layer 140L may be formed on the plurality of word lines WL, the second gate insulating material layer Gox_2L, and the second insulating pattern 132. For example, the third insulating layer 140L may be formed through a deposition process.

The third insulating layer 140L may cover side surfaces of the plurality of word lines WL in the first direction DR1. The third insulating layer 140L may cover the surfaces of the second gate insulating material layer Gox_2L and the second insulating pattern 132 facing each other in the third direction DR3. The third insulating layer 140L may further cover a side surface of the second gate insulating material layer Gox_2L in the first direction DR1, which is positioned on side surfaces of the plurality of sacrificial semiconductor layers 122 and the plurality of first gate insulating layers Gox_1 in the first direction DR1. The third insulating layer 140L may further cover a side surface of the second insulating pattern 132 in the first direction DR1.

The third insulating layer 140L may extend in the second direction DR2 between a plurality of pairs of sacrificial semiconductor layers 122 that are spaced apart and arranged in the third direction DR3 between capacitors CAP that are spaced apart in the first direction DR1. Each pair of sacrificial semiconductor layers 122 may include two sacrificial semiconductor layers 122 positioned between capacitors CAP spaced apart in the first direction DR1 and spaced apart from each other in the first direction DR1 to face each other.

FIG. 49 is a cross-sectional view taken along the C-C' line of FIG. 48.

As illustrated in FIG. 48 and FIG. 49, a plurality of fourth trenches T4 may be formed to expose side surfaces of the plurality of sacrificial semiconductor layers 122 in the first direction DR1 and side surfaces of the plurality of first gate insulating layers Gox_1 in the first direction DR1.

First, a photoresist layer covering the upper surfaces of the third insulating layer 140L and the second gate insulating material layer Gox_2L may be formed, and a photoresist pattern exposing portions of the third insulating layer 140L and the second gate insulating material layer Gox_2L to be removed through a photolithography process may be formed. An etching process may be performed using the photoresist pattern to remove portions of the third insulating layer 140L and the second gate insulating material layer Gox_2L. Portions of the second gate insulating material layer Gox_2L and a third insulating layer 140L that cover side surfaces of the plurality of sacrificial semiconductor layers 122 in the first direction DR1 and side surfaces of the plurality of first gate insulating layers Gox_1 in the first direction DR1 may be removed by an etching process. Portions of the second insulating pattern 132, which overlap the portions of the second gate insulating material layer Gox_2L covering side surfaces of the plurality of sacrificial semiconductor layers 122 in the first direction DR1 and side surfaces of the plurality of first gate insulating layers Gox_1 in the first direction DR1, in the third direction DR3, may be removed together. A portion of the third insulating layer 140L positioned on a side surface of each of the second insulating pattern 132 in the first direction DR1 may be removed. Portions of the third insulating layer 140L positioned between surfaces of the second gate insulating material layer Gox_2L and the second insulating pattern 132 facing each other in the third direction DR3 may remain without being removed.

As a result of removal of portions of the third insulating layer 140L, the second gate insulating material layer Gox_2L, and the second insulating pattern 132, the plurality of fourth trenches T4 may be formed. Side surfaces of the plurality of sacrificial semiconductor layers 122 in the first direction DR1, and side surfaces of the plurality of first gate insulating layers Gox_1 in the first direction DR1 may be exposed through the plurality of fourth trenches T4. A portion of an upper surface of the substrate 110 may be exposed through the plurality of fourth trenches T4.

Portions of the second gate insulating material layer Gox_2L and portions of the third insulating layer 140L remaining after the etch process may be referred to as the second gate insulating layer Gox_2 and the third insulating pattern 140, respectively. The first gate insulating layer Gox_1 and the second gate insulating layer Gox_2 may form the gate insulating layer Gox. A side surface of the third insulating pattern 140 in the first direction DR1 may form a coplanar surface with side surfaces of the plurality of sacrificial semiconductor layers 122 in the first direction DR1 and side surfaces of the plurality of first gate insulating layers Gox_1 in the first direction DR1. A side surface of the second gate insulating layer Gox_2 in the first direction DR1 may form a coplanar surface with a side surface of the second insulating pattern 132 in the first direction DR1 and a side surface of the third insulating pattern 140 in the first direction DR1.

In a cross-section according to the second direction DR2 and the third direction DR3, the plurality of fourth trenches T4 may be spaced apart and arranged in the second direction DR2. The third insulating pattern 140 may be positioned on both side surfaces of the plurality of fourth trenches T4 in the second direction DR2. A plurality of bit lines BL formed in a subsequent process may be spaced apart in the second direction DR2 by the third insulating pattern 140.

FIG. 51 is a cross-sectional view taken along the line A-A' of FIG. 50.

As shown in FIGS. 50 and 51, the plurality of sacrificial semiconductor layers 122 may be removed through the plurality of fourth trenches T4.

For example, an etching process may be performed using a material having a high etch selectivity for the first gate insulating layer Gox_1, the second gate insulating layer Gox_2, the second insulating pattern 132, and the third insulating pattern 140 with respect to the sacrificial semiconductor layer 122. The plurality of sacrificial semiconductor layers 122 may be selectively etched by an etch process, and the plurality of first gate insulating layers Gox_1, second gate insulating layers Gox_2, second insulating pattern 132, and third insulating pattern 140 may be hardly etched. Side surfaces of the plurality of sacrificial semiconductor layers 122 in the first direction DR1, which are arranged spaced apart in the third direction DR3 may be exposed, through the plurality of fourth trenches T4. The plurality of sacrificial semiconductor layers 122 may be etched in a side direction for example, the first direction DR1. As the plurality of sacrificial semiconductor layers 122 are removed, side surfaces of the plurality of first capacitor electrodes 171 in the first direction DR1 may be exposed.

In a cross-section along the second direction DR2 and the third direction DR3, as the plurality of sacrificial semiconductor layers 122 are removed, a plurality of empty spaces surrounded by the gate insulating layer Gox may be formed. Each of the plurality of empty spaces may be defined by surfaces of a pair of first gate insulating layers Gox_1 facing each other in the third direction DR3, and by surfaces of the second gate insulating layer Gox_2 surrounding the pair of first gate insulating layers Gox_1 facing each other in the second direction DR2. The plurality of empty spaces may be spaced apart and arranged in the second direction DR1 and the third direction DR3.

For example, the sacrificial semiconductor layer 122 and the substrate 110 may include the same semiconductor material. In this case, a portion of the upper surface of the substrate 110 exposed through the plurality of fourth trenches T4 may be etched together with the plurality of sacrificial semiconductor layers 122.

FIG. 53 is a cross-sectional view taken along line A-A' of FIG. 52, and FIG. 54 is a cross-sectional view taken along line C-C' of FIG. 52.

As shown in FIGS. 52 to 54, a channel material layer CHL may be formed on the plurality of first capacitor electrodes 171 and the gate insulating layer Gox.

For example, through a deposition process, the channel material layer CHL covering the plurality of first capacitor electrodes 171 and the gate insulating layer Gox with a uniform thickness may be formed. The channel material layer CHL may cover side surfaces of the plurality of first capacitor electrodes 171 in the first direction DR1. The channel material layer CHL may cover surfaces of each pair of first gate insulating layers Gox_1 facing each other in the third direction DR3, and surfaces of the second gate insulating layer Gox_2 surrounding each pair of first gate insulating layers Gox_1 facing each other in the second direction DR2. Each pair of first gate insulating layers Gox_1 may include two first gate insulating layers Gox_1 positioned on a side surface of each first capacitor electrode 171 in the first direction DR1.

The channel material layer CHL may further cover a side surface of each of the plurality of first gate insulating layers Gox_1, the second gate insulating layer Gox_2, the second insulating pattern 132, and the third insulating pattern 140 in the first direction DR1. The channel material layer CHL may further cover both side surfaces of the third insulating pattern 140 in the second direction DR2.

In some implementations, the thickness of the channel material layer CHL may be about 2 nm to about 4 nm. The thickness of the channel material layer CHL may refer to the thickness of the channel material layer CHL in the first direction DR1 positioned on the first capacitor electrode 171, the thickness of the channel material layer CHL in the third direction DR3 positioned on the first gate insulating layer Gox_1, and the thickness of the channel material layer CHL in the second direction DR2 positioned on the second gate insulating layer Gox_2.

As the thickness of the channel material layer CHL is about 2 nm to about 4 nm, an empty space surrounded by the channel material layer CHL may be formed between each pair of first gate insulating layers Gox_1.

The channel material layer CHL may include an oxide semiconductor material. For example, the channel material layer CHL may include IGZO (indium gallium zinc oxide), but is not limited thereto.

Subsequently, an annealing process may be performed under an O₂or air atmosphere. O may diffuse into the channel material layer CHL from O2 or air during the annealing process. O2 or air may contact the surfaces of portions of the channel material layer CHL that overlap the word line WL in the third direction DR3 through the empty space surrounded by the channel material layer CHL, and O may diffuse in a short time through portions of the channel material layer CHL that overlap the word line WL in the third direction DR3. Accordingly, it may be easy to adjust the carrier concentration of portions of the channel material layer CHL overlapping the word line WL in the third direction DR3 to a desired concentration.

FIG. 56 is a cross-sectional view taken along the A-A' line of FIG. 55, and FIG. 57 is a cross-sectional view taken along the C-C' line of FIG. 55.

As illustrated in FIGS. 55 to 57, a spacer material layer SPL may be formed on the channel material layer CHL.

For example, the spacer material layer SPL may fill a space surrounded by the channel material layer CHL through a deposition process. The spacer material layer SPL may cover a side surface, in the first direction DR1, of the channel material layer CHL which covers side surfaces of the plurality of first capacitor electrodes 171 in the first direction DR1. The spacer material layer SPL may cover the surfaces, facing each other in the third direction DR3, of the channel material layer CHL, which cover the surfaces of each pair of first gate insulating layers Gox_1 facing each other in the third direction DR3. The spacer material layer SPL may cover surfaces, facing each other in the second direction DR2, of the channel material layer CHL, which covers surfaces, facing each other in the second direction DR2, of the second gate insulating layer Gox_2 surrounding each pair of first gate insulating layers Gox_1. Each pair of first gate insulating layers Gox_1 may include two first gate insulating layers Gox_1 positioned on a side surface of each first capacitor electrode 171 in the first direction DR1.

The spacer material layer SPL may include an insulating material. For example, the insulating material may include an oxide such as SiOx, Al₂O₃, HfO₂, or GaOx, or a nitride such as SiN. However, the insulating material is not limited thereto, and may include other different dielectric materials.

FIG. 59 is a cross-sectional view taken along line C-C' of FIG. 58.

As illustrated in FIG. 58 and FIG. 59, a plurality of fifth trenches T5 exposing a side surface of the channel material layer CHL in the first direction DR1 may be formed.

First, a photoresist layer covering the upper surfaces of the channel material layer CHL and the spacer material layer SPL may be formed, and a photoresist pattern exposing portions of the channel material layer CHL and the spacer material layer SPL to be removed through a photolithography process may be formed. An etch process may be performed using the photoresist pattern to remove portions of the channel material layer CHL and the spacer material layer SPL. Portions of the channel material layer CHL and the spacer material layer SPL covering a side surface of each of the plurality of first gate insulating layers Gox_1, the second gate insulating layer Gox_2, the second insulating pattern 132, and the third insulating pattern 140 in the first direction DR1 may be removed by an etching process. Portions of the channel material layer CHL and the spacer material layer SPL positioned between surfaces of each pair of first gate insulating layers Gox_1 facing each other in the third direction DR3 may remain without being removed. Portions of the channel material layer CH) and the spacer material layer SPL positioned between surfaces of the second gate insulating layer Gox_2 surrounding each pair of the first gate insulating layers Gox_1 facing each other in the second direction DR2 may remain without being removed. Portions of the channel material layer CHL and the spacer material layer SPL covering a side surface of each of the plurality of first capacitor electrodes 171 in the first direction DR1 may remain without being removed. Portions of the channel material layer CHL and the spacer material layer SPL remaining after the etch process may be referred to as the channel pattern CH and spacer SP, respectively.

A plurality of channel patterns CH may be spaced apart and arranged in the third direction DR3 and the second direction DR2. Each of the plurality of channel patterns CH extends in the first direction DR1, and may have a pillar shape with an interior that is hollow. Each of the plurality of channel patterns CH may include one end portion opened along the first direction DR1 and the other end portion closed. One end portion of each channel pattern CH is connected to the bit line BL, and the other end portion of each channel pattern CH may be connected to the capacitor CAP (for example, the first capacitor electrode 171 of the capacitor CAP).

Each spacer SP of the plurality of spacers may be positioned in a space surrounded by each channel pattern CH of the plurality of channel patterns. Each of the plurality of spacers SP may be surrounded by each of the plurality of channel patterns CH. Both side surfaces of each spacer SP in the second direction DR2 and in the third direction DR3 may be surrounded by each channel pattern CH. Each spacer SP may be spaced apart from the capacitor CAP (for example, the first capacitor electrode 171 of the capacitor CAP) by each channel pattern CH.

Side surfaces of the plurality of channel patterns CH in the first direction DR1 exposed by the plurality of fifth trenches T5 may be coplanar with a side surface of each of the plurality of first gate insulating layers Gox_1, the second gate insulating layer Gox_2, the second insulating pattern 132, and the third insulating pattern 140 in the first direction DR1. The other side surfaces of the plurality of channel patterns CH in the first direction DR1 exposed by the plurality of fifth trenches T5 may be connected to the plurality of capacitors CAP, respectively.

In some implementations, side surfaces of a plurality of spacers SP in the first direction DR1 exposed by the plurality of fifth trenches T5 may be coplanar with side surfaces of a plurality of channel patterns CH in the first direction DR1 exposed by the plurality of fifth trenches T5, but is not limited thereto. For example, after removing portions of the channel material layer CHL and the spacer material layer SPL, a further portion of the spacer material layer SPL may be removed. As another example, an etch-back process for the spacer material layer SPL may be performed before removing a portion of the channel material layer CHL, so that a portion of the spacer material layer SPL may be removed. Accordingly, side surfaces of the plurality of spacers SP in the first direction DR1 exposed by the plurality of fifth trenches T5 may be spaced further from the center of each fifth trench T5 than side surfaces of the plurality of channel patterns CH in the first direction DR1 exposed by the plurality of fifth trenches T5. In this case as well, each spacer SP may overlap with the word line WL in the third direction DR3, and the width of a region of the spacer SP overlapping the word line WL in the third direction DR3 along the first direction DR1 may be the same as the width of the word line WL along the first direction DR1. In this case, in a subsequent process, a portion of the bit line BL may be formed inside a space surrounded by the channel pattern CH, and as illustrated in FIG. 7 and FIG. 8, the bit line BL may include a plurality of protrusion portions BLP extending in the first direction DR1. The plurality of protrusion portions BLP may not overlap the word line WL in the third direction DR3. For example, when the bit line BL is including the first conductive layer 151 and the second conductive layer 152, it may be as in the implementation shown in FIG. 7. In another example, when the bit line BL is formed of a single layer, it may be the same as the implementation illustrated in FIG. 8.

In some implementations, the spacer SP may include an oxide insulating material. In this case, the annealing process under the above-described O₂ or air atmosphere may be performed after forming the spacer SP. Since the spacer SP is including O, the diffusion speed of O in the spacer SP may be fast. Accordingly, O diffused into the spacer SP may contact the surfaces of portions of the channel pattern CH overlapping the word line WL in the third direction DR3, and O may be rapidly diffused into the portions of the channel material layer CHL overlapping the word line WL in the third direction DR3. Accordingly, it may be easy to adjust the carrier concentration of portions of the channel pattern CH that overlap the word line WL in the third direction DR3 to a desired concentration.

FIG. 61 is a cross-sectional view taken along line C-C' of FIG. 60.

As illustrated in FIG. 60 and FIG. 61, a plurality of bit lines BL may be formed respectively in the plurality of fifth trenches T5.

First, the first conductive layer 151 may be formed on the inner surface of each fifth trench T5 through a deposition process. The first conductive layer 151 may cover side surfaces of a plurality of channel patterns CH in the first direction DR1, which are spaced apart and arranged in the third direction DR3. The first conductive layer 151 may cover side surfaces of the plurality of spacers SP in the first direction DR1, which are spaced apart and arranged in the third direction DR3. The first conductive layer 151 may cover side surfaces of the plurality of first gate insulating layers Gox_1 in the first direction DR1, which are arranged spaced apart in the third direction DR3. The first conductive layer 151 may cover a side surface of the second gate insulating layer Gox_2, the second insulating pattern 132, and the third insulating pattern 140, the second gate insulating layer Gox_2 in the first direction DR1, which are positioned between the plurality of first gate insulating layers Gox_1 spaced apart and arranged in the third direction DR3.

The first conductive layer 151 may extend in the third direction DR3 and may have a pillar shape having a hollow interior. The first conductive layer 151 may be electrically connected to the plurality of channel patterns CH arranged spaced apart in the third direction DR3. The first conductive layer 151 may be electrically connected to two channel patterns CH spaced apart in the first direction DR1. In some implementations, the first conductive layer 151 may be in contact with a side surface of the channel pattern CH in the first direction DR1.

In some implementations, the first conductive layer 151 may include an oxide semiconductor material. The first conductive layer 151 may include the same oxide semiconductor material as the channel pattern CH, but is not limited thereto. Since both the first conductive layer 151 and the channel pattern CH include an oxide semiconductor material, the contact resistance between the bit line BL and the channel pattern CH may be reduced.

Subsequently, the second conductive layer 152 may be formed on the first conductive layer 151 through a deposition process. The second conductive layer 152 may fill the remaining space in each fifth trench T5 after the first conductive layer 151 is formed. The second conductive layer 152 may have a pillar shape extending in the third direction DR3. The outer surface of the second conductive layer 152 may be surrounded by the first conductive layer 151.

The second conductive layer 152 may include a doped semiconductor material such as doped silicon or doped germanium, a conductive metal nitride such as titanium nitride or tantalum nitride, a metal such as tungsten, titanium, or tantalum, a metal-semiconductor compound such as tungsten silicide, cobalt silicide, or titanium silicide, or a combination thereof.

As shown in FIG. 60 and FIG. 61, the bit line BL is connected to the substrate 110, but the bit line BL and the substrate 110 may be electrically insulated. For example, although not shown, an insulating layer may be positioned between the substrate 110 and the bit line BL. As another example, after removing the substrate 110 in a subsequent process, the stacked structure from which the substrate 110 has been removed may be bonded on a different substrate, and the bit line BL of the bonded substrate and the laminated structure may be electrically insulated.

According to the processes illustrated in FIGS. 55- 57, the spacer SP may be formed in a space surrounded by the channel pattern CH, but implementations are not limited thereto. For example, the processes shown in FIGS. 55- 57 may be omitted. For example, when the bit line BL is formed without forming the spacer material layer SPL after the processes of FIGS. 52 - 54, as shown in FIG. 6, the air gap AG may be formed in the space surrounded by the channel pattern CH. When the inner diameter of the space surrounded by the channel pattern CH is equal to or less than a threshold value, the first conductive layer 151 and the second conductive layer 152 may be scarcely formed in the space surrounded by the channel pattern CH, and may cover a side surface of the channel pattern CH in the first direction DR1 and have a shape extending in the third direction DR3. Accordingly, the air gap AG may be formed naturally between the channel pattern CH and the bit line BL.

In some implementations, an aspect of the present disclosure provides a method of manufacturing a semiconductor device according to some implementations includes: forming a plurality of sacrificial insulating layers and a plurality of sacrificial semiconductor layers which are spaced apart and arranged in a first direction parallel to an upper surface of a substrate, a second direction intersecting the first direction, and a third direction perpendicular to the upper surface of the substrate, on the substrate; removing a portion of the plurality of sacrificial insulating layers and a portion of the plurality of sacrificial semiconductor layers; forming a plurality of first capacitor electrodes on side surfaces in the first direction of the plurality of sacrificial semiconductor layers exposed as the portion of the plurality of sacrificial semiconductor layers are removed; forming a plurality of capacitors by forming a dielectric layer, a second capacitor electrode, and a plate electrode on the plurality of first capacitor electrodes; removing a remaining portion of the plurality of sacrificial insulating layers; forming a gate insulating layer and a plurality of word lines extending in the second direction on side surfaces of the plurality of capacitors in the first direction exposed as the remaining portion of the plurality of sacrificial insulating layers are removed; removing a remaining portion of the plurality of sacrificial semiconductor layers; forming a plurality of channel patterns including an oxide semiconductor material on side surfaces of the plurality of capacitors in the first direction exposed as the remaining portion of the plurality of sacrificial semiconductor layers are removed; annealing in an O₂ or air atmosphere; and forming a plurality of bit lines extending in the third direction on side surfaces of the plurality of channel patterns in the first direction. In a cross-section along the first direction and the third direction, each of the plurality of channel patterns includes first portions extending in the first direction and spaced apart in the third direction, and a second portion connecting the first portions and extending in the third direction along a side surface of each capacitor in the first direction.

In some implementations, the step of forming the plurality of channel patterns may include a step of forming a channel material layer covering inner surfaces of spaces from which the plurality of sacrificial semiconductor layers have been removed with a uniform thickness, and a step of removing a portion of the channel material layer to form the plurality of channel patterns. An empty space surrounded by the channel material layer may be formed in the space where each of the sacrificial semiconductor layers has been removed. The empty space surrounded by the channel material layer may overlap the word line in the third direction.

In some implementations, the method may further include a step of forming a plurality of spacers including an insulating material after forming the plurality of channel patterns. Each spacer may be formed in a space surrounded by the first portions and the second portion of each channel pattern.

In some implementations, the step of forming the plurality of spacers may include forming a spacer material layer on the channel material layer, and removing a portion of the spacer material layer together with a portion of the channel material layer to form the plurality of spacers. The plurality of spacers may be formed in the empty space surrounded by the channel material layer.

In some implementations, the plurality of spacers may include an oxide insulating material, and the annealing may be performed after forming the plurality of spacers.

In some implementations, the step of forming the plurality of bit lines may include a step of forming a first conductive layer including an oxide semiconductor material on side surfaces of the plurality of channel patterns in the first direction, and a step of forming a second conductive layer different from the first conductive layer on the first conductive layer.

In some implementations, in the first direction, a side surface of each spacer adjacent to each bit line may be positioned between both side surfaces of each channel pattern. Each bit line may be further formed on the side surface of each spacer in the first direction in the empty space surrounded by each channel pattern.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although implementations of the present invention have been described in detail above, the scope of rights of the present invention is not limited thereto, and various modified and improved forms by those skilled in the art using the basic concept of the present invention defined in the following claims also belong to the scope of rights of the present invention.

What is claimed is:

1. A semiconductor device comprising:
a substrate;
a plurality of channel patterns spaced apart and arranged on the substrate in a direction perpendicular to an upper surface of the substrate, each channel pattern of the plurality of channel patterns comprising a first side surface and a second side surface facing opposite directions along a first direction parallel to the upper surface of the substrate;
a bit line connected to the first side surface of each channel pattern of the plurality of channel patterns and extending in a direction perpendicular to the upper surface of the substrate;
a capacitor connected to the second side surface of each channel pattern of the plurality of channel patterns;
a word line extending across the plurality of channel patterns in a second direction intersecting the first direction; and
a gate insulating layer positioned between the plurality of channel patterns and the word line,
wherein, in a cross-section along the first direction and the direction perpendicular to the upper surface of the substrate, wherein the direction perpendicular to the upper surface of the substrate is a third direction, each channel of the plurality of channel patterns comprises
a plurality of first portions extending in the first direction and spaced apart in the third direction, and
a second portion connecting the first portions, and
wherein the second portion extends in the third direction along a side surface of the capacitor in the first direction.

2. The semiconductor device of claim 1, comprising a spacer between the plurality of first portions, and between the second portion and the bit line.

3. The semiconductor device of claim 2,
wherein the spacer overlaps the word line in the third direction, and
wherein, a width, along the first direction, of a region of the spacer overlapping the word line in the third direction, is equal to a width of the word line along the first direction.

4. The semiconductor device of claim 2,
wherein, in a cross-section along the second direction and the third direction, the spacer is completely surrounded by a respective channel pattern of the plurality of channel patterns.

5. The semiconductor device of claim 2,
wherein the spacer comprises an insulating material.

6. The semiconductor device of claim 1,
wherein an air gap is positioned between the plurality of first portions, and between the second portion and the bit line.

7. The semiconductor device of claim 1,
wherein each channel pattern of the plurality of channel patterns comprises an oxide semiconductor material.

8. The semiconductor device of claim 7,
wherein the bit line comprises (i) a first conductive layer on the plurality of channel patterns and (ii) a second conductive layer on the first conductive layer, and
wherein the first conductive layer comprises an oxide semiconductor material.

9. The semiconductor device of claim 1,
wherein the bit line overlaps the plurality of channel patterns in the first direction and the third direction.

10. The semiconductor device of claim 9,
wherein a plurality of portions of the bit line overlap the plurality of channel patterns in the third direction, each portion of the plurality portions being positioned between the plurality of first portions of a respective one of the plurality of channel patterns.

11. A semiconductor device comprising:
a substrate;
a plurality of channel patterns spaced apart and arranged on the substrate in a direction perpendicular to an upper surface of the substrate, each channel pattern of the plurality of channel patterns comprising a first side surface and a second side surface facing opposite directions along a first direction parallel to the upper surface of the substrate;
a bit line connected to the first side surface of each channel pattern of the plurality of channel patterns and extending in a direction perpendicular to the upper surface of the substrate;
a capacitor connected to the second side surface of each channel pattern of the plurality of channel patterns;
a word line extending across the plurality of channel patterns in a second direction intersecting the first direction; and
a gate insulating layer between the plurality of channel patterns and the word line,
wherein each channel pattern of the plurality of channel patterns covers surfaces of the gate insulating layer, that face each other in the direction perpendicular to the upper surface of the substrate and a side surface of the capacitor in the first direction with a uniform thickness, wherein the direction perpendicular to the upper surface of the substrate is a third direction.

12. The semiconductor device of claim 11,
wherein each channel pattern of the plurality of channel patterns comprises:
a plurality of first portions covering the surfaces of the gate insulating layer facing each other in the third direction, and
a second portion covering a side surface facing the first direction of the capacitor.

13. The semiconductor device of claim 12,
wherein a thickness of each first portion of the plurality of first portions in the third direction is 2 nm to 4 nm.

14. The semiconductor device of claim 12, further comprising a spacer between the plurality of first portions and between the bit line and the second portion, and
wherein the spacer comprises an insulating material.

15. The semiconductor device of claim 14,
wherein the spacer extends from an inner surface of the second portion toward the bit line in the first direction, and
wherein the spacer overlaps the word line in the third direction.

16. The semiconductor device of claim 15,
wherein a distance between the spacer and the bit line in the first direction is equal to or less than a distance between the word line and the bit line in the first direction.

17. The semiconductor device of claim 12,
wherein an air gap is between the plurality of first portions, and between the bit line and the second portion.

18. The semiconductor device of claim 12,
wherein the bit line comprises a plurality of protrusion portions protruded in the first direction, and
wherein each protrusion of the plurality of protrusion portions overlaps the plurality of first portions in the third direction.

19. The semiconductor device of claim 11,
wherein each channel pattern of the plurality of channel patterns comprises an oxide semiconductor material.

20. A semiconductor device comprising:
a substrate;
a plurality of channel patterns that are spaced apart and arranged on the substrate in a direction perpendicular to an upper surface of the substrate, each channel pattern of the plurality of channel patterns comprising a first side surface and a second side surface that face opposite directions along a first direction parallel to the upper surface of the substrate;
a bit line connected to the first side surface of each of the plurality of channel patterns and extending in the direction perpendicular to the upper surface of the substrate;
a capacitor connected to the second side surface of each of the plurality of channel patterns;
a word line extending across the plurality of channel patterns in a second direction intersecting the first direction;
a gate insulating layer between the plurality of channel patterns and the word line; and
a spacer surrounded by each channel pattern of the plurality of channel patterns and overlapping the word line in the direction perpendicular to the upper surface of the substrate, wherein the direction perpendicular to the upper surface of the substrate is a third direction,
wherein each channel pattern of the plurality of channel patterns comprises an oxide semiconductor material, and
wherein the spacer comprises an insulating material.
